(19) United States
(12) Patent Application Publication
(10) Pub. No.: US 2007/0277930 A1
(43) Pub. Date: Dec. 6, 2007

(54) Substrate Cleaning Apparatus and Substrate Processing Unit

(76) Inventors: Toshi Yokoyama, Tokyo (JP); Seiji Katsuoka, Tokyo (JP); Takahiro Ogawa, Tokyo (JP); Kaoru Yamada, Tokyo (JP); Kazuaki Maeda, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 11/663,071

(22) PCT Filed: Sep. 14, 2005
(86) PCT No.: PCT/JP05/17318

§ 371 Date: Mar. 16, 2007

(30) Foreign Application Priority Data
Sep. 17, 2004 (JP) 2004-271875
Aug. 29, 2005 (JP) 2005-247070

(51) Int. Cl. H01L 21/304; H01L 21/683

(52) U.S. Cl. 156/345.31; 156/345.33; 156/345.55

(57) ABSTRACT

A substrate cleaning apparatus does not need positioning of a transport system on start-up of the apparatus and can reduce the installation area of the apparatus. The substrate cleaning apparatus includes a base-integrated frame (1) in which are mounted a substrate transport device (2) for transporting a substrate, at least one substrate processing unit (3) for processing the substrate, a substrate loading port (5) for placing a substrate-housing cassette (4) on it, and a processing liquid supply apparatus (6) for supplying a processing liquid to the substrate processing unit, wherein maintenance of the substrate processing unit (3) can be performed from the backside of the apparatus.

### TECHNICAL FIELD

The present invention relates to a substrate cleaning apparatus and a substrate processing unit for carrying out cleaning processing of a substrate (e.g., semiconductor wafer) for use in the manufacturing of a semiconductor device.

### BACKGROUND ART

In the manufacturing of a semiconductor device, various processings of a substrate are carried out in many processing steps. Especially because of recent diversification of processing steps, the number of substrate processing units mounted in an apparatus for use in processing steps is increasing, making integration of such processing units difficult. Thus, in many cases, a plurality of substrate processing units are employed in combination in one apparatus (see Japanese Patent Laid-Open Publication No. 2003-77879).

In the case of such an apparatus including a combination of substrate processing units, positioning of a transport system for transporting a substrate between the substrate processing units is necessary on the start-up of the apparatus. The positioning of transport system necessitates a considerable time with an increased cost. Further, when a large number of processing units are necessary for high productivity, a reduction in the installation area of the apparatus can be made with difficulty.

With respect to a substrate processing unit for carrying out bevel etching and cleaning of a substrate respectively with a processing liquid, etching, cleaning and liquid removal/drying steps are carried out sequentially in the same unit. In the etching or cleaning step, the processing liquid can adhere to various parts in the substrate processing unit, and the liquid will take the form of fine particles or a mist during the liquid removal/drying step and such particles or mist can contaminate a substrate. Prevention of such secondary contamination is therefore an important problem.

### DISCLOSURE OF INVENTION

The present invention has been made in view of the above situation in the art. It is therefore an object of the present invention to provide a substrate cleaning apparatus which does not require positioning of a transport system on start-up of the apparatus and which enable a reduction in the installation area of the apparatus.

It is another object of the present invention to effectively prevent secondary contamination of a substrate with an extraneous substance in a substrate processing unit, especially in a downsized apparatus.

In order to achieve these objects, the present invention provides a substrate cleaning apparatus comprising a base-integrated frame in which are mounted a substrate transport device for transporting a substrate, at least one substrate processing unit for processing the substrate, a substrate loading port for placing a substrate-housing cassette thereon, and a processing liquid supply apparatus for supplying a processing liquid to the substrate processing unit, wherein maintenance of the substrate processing unit can be performed from the backside of the apparatus.

According to the present invention, substrate processing units in any desired combination, together with the substrate transport device, the substrate loading port and the processing liquid supply apparatus, can be mounted in the same base-integrated frame. This can provide a multi-process substrate cleaning apparatus capable of dealing with more than one process. Further, because of the integral structure, the substrate cleaning apparatus can be transported without separation while maintaining the position of the substrate transport system in the apparatus. This can eliminate the need for an operation for positioning of the substrate transport system upon installation of the apparatus, thus considerably shortening the start-up time of the apparatus. Further, the installation area of the apparatus can be minimized. In addition, maintenance of the processing unit(s) can be performed from the backside of the apparatus. This can facilitate the maintenance.

At least one of the at least one substrate processing unit may be a substrate processing unit capable of completing a substrate processing process by itself by carrying out a final drying step.

The use of such a substrate processing unit, which can complete a substrate processing process by itself, enables downsizing of the apparatus.

At least one of the at least one substrate processing unit may be a substrate processing unit capable of carrying out at least one of cleaning of the both surfaces of the substrate, bevel etching of the substrate and scrubbing of one surface of the substrate, and also capable of carrying out drying of the substrate.

The use of such a substrate processing unit, which can carry out drying and at least one of two-surface cleaning, bevel etching and one-surface scrubbing of the substrate, enables downsizing of the apparatus.

The present invention provides another substrate cleaning apparatus comprising: a substrate loading port for placing a substrate-housing cassette thereon; a substrate processing unit for processing a substrate; and a substrate transport device, disposed between the substrate loading port and the substrate processing unit, for transporting the substrate only between the substrate loading port and the substrate processing unit.

According to the present invention, the substrate cleaning apparatus, in which the substrate transport device is disposed between the substrate loading port and the substrate processing unit and transports a substrate only between the substrate loading port and the substrate processing unit, can shorten the substrate transport distance, thereby minimizing the generation of particles.

Preferably, the substrate processing unit is disposed parallel to the substrate loading port.

By disposing the substrate processing unit parallel to the substrate loading port, the substrate transport distance between the substrate loading port and the substrate processing unit can be shortened and unnecessary delivery/receipt of the substrate can be eliminated. This makes it possible to transport the substrate by a minimum operation and to minimize the generation of particles.

Preferably, the processing liquid supply apparatus is capable of supplying two or more types of processing liquids to the substrate processing unit.

Such a processing liquid supply apparatus, without a change, can deal with the use of a substrate processing unit that employs a plurality of processing liquids.

The processing liquid supply apparatus may include a plurality of supply tanks for each processing liquid.

With the provision in the processing liquid supply apparatus of a plurality of supply tanks for each processing liquid, even when a processing liquid in one supply tank has run out, supply of the processing liquid can be continued by switching to another supply tank, thus enabling continued processing of a substrate.

In this case, the processing liquid is preferably supplied alternately from the plurality of supply tanks.

Processing of a substrate can be carried out in a continuous manner by supplying the processing liquid alternately from the plurality of supply tanks.

Preferably, a substrate drying means is provided in all of the at least one substrate processing unit.

A substrate in a dry state can therefore be always taken out of any substrate processing unit. Accordingly, the transport device and the interior of the substrate cleaning apparatus are free from contamination with a processing liquid, or the like.

Preferably, the substrate drying means includes a gas jet means for jetting an inert gas to the front and back surfaces of the substrate.

The use of such a gas jet means can simultaneously dry the front and back surfaces of a substrate.

Preferably, the substrate cleaning apparatus includes a purge plate for jetting an inert gas toward a peripheral portion of the substrate for drying of the substrate surface after the bevel etching of the substrate in the substrate processing unit.

The use of such a purge plate can remove a liquid remaining on the bevel portion of the substrate after the bevel etching, and rapidly dry the substrate surface.

The purge plate is preferably adapted to jet the inert gas from at least two openings, one facing a peripheral portion of the substrate and the other facing an inner portion of the substrate.

By first jetting an inert gas toward the inner portion of the substrate and then jetting the inert gas toward the peripheral portion of the substrate from the purge plate upon drying of the substrate, the etched bevel portion of the substrate can be dried while forcing a liquid, remaining on a peripheral region of the substrate, out of the substrate.

Preferably, the substrate transport device is a fixed transport robot without a travel axis.

The use of such a fixed transport robot without a travel axis can minimize the generation of particles.

The present invention also provides a substrate processing apparatus comprising: a substrate transport device for transporting a substrate; a substrate processing unit for processing the substrate; a substrate loading port for placing a substrate-housing cassette thereon; and a processing liquid supply apparatus for supplying a processing liquid to the substrate processing unit, wherein the following relation is maintained:

PA>PO>PB,

wherein PO represents atmospheric pressure outside the substrate processing apparatus, PA represents air pressure in a substrate transport chamber in which the substrate transport device is disposed, and PB represents air pressure in the substrate processing unit.

Because of the relation: air pressure PA in the substrate transport chamber>atmospheric pressure PO outside the substrate processing apparatus>air pressure PB in the substrate processing unit, the external air outside the apparatus will not flow into the substrate transport chamber, and therefore a substrate, which has undergone cleaning processing in the substrate processing unit, will not be contaminated with particles, etc. in an airflow flowing from outside.

The present invention also provides a substrate processing unit for use in a processing area to which a clean gas is supplied, comprising: a chamber disposed in the processing area; a substrate holder for holding a substrate rotatably in a horizontal plane in the chamber; and a processing fluid supply means for supplying a processing fluid to the substrate held by the substrate holder, wherein the chamber is provided with a gas flow-creating means for creating a gas flow, uniformly encircling the substrate held by the substrate holder, by taking said clean gas into the chamber from a gas intake formed above the substrate holder, and discharging the gas from the bottom of the chamber.

According to the present invention, the substrate held by the substrate holder can be shielded by a downward flow of clean gas (air curtain), thereby preventing movement of a contaminant from the inner wall of the chamber or a mechanism in the chamber to the substrate. Further, during processing of the substrate, a processing liquid, etc. can be prevented from spattering on the inner wall of the chamber or a mechanism in the chamber. Secondary contamination of a substrate can therefore be prevented or reduced.

Preferably, the gas intake is formed along a periphery of the substrate held by the substrate holder.

Such a gas intake can create a downward gas flow in a cylindrical form ranging from the gas intake to the substrate holder, thus effectively shielding the substrate.

The present invention provides another substrate processing unit for use in a processing area to which a clean gas is supplied, comprising: a chamber disposed in the processing area; a substrate holder for holding a substrate rotatably in a horizontal plane in the chamber; a processing fluid supply means for supplying a processing fluid to the substrate held by the substrate holder; and a purge member for covering a surface of the substrate with a gap therebetween and supplying a gas into the gap to prevent intrusion of the processing fluid into the gap, wherein the purge member comprises a first cover member for covering a first area of the substrate surface and a second cover member for covering a second area of the substrate surface, at least one of the cover members being movable with respect to the other.

According to the present invention, the first cover member or the second cover member can be selectively brought close to a substrate so that the surface of the substrate is partly exposed and partly covered. This enables both effective processing and protection of the substrate surface.

Preferably, the substrate holder comprises a plurality of rollers, each having a vertical axis and provided with a roller cover having an opening for the roller to hold the substrate.

Since the roller cover, except the opening necessary for holding a substrate, covers the roller, adhesion of a processing liquid to the roller can be prevented, and therefore secondary contamination of a substrate via the roller can be prevented or reduced.

Preferably, the above substrate processing units each include a gas nozzle for jetting a gas towards the substrate, and a nozzle cover for covering the gas nozzle when not in use.

Since the gas nozzle, when not in use, is covered with the nozzle cover, adhesion of a processing liquid to the gas nozzle can be prevented, and therefore secondary contamination of a substrate via the gas nozzle can be prevented or reduced.

Preferably, the above substrate processing units each include a cleaning liquid supply means for cleaning the inner wall of the chamber with predetermined timing.

By thus cleaning the inner wall of the chamber with predetermined timing, secondary contamination of a substrate via the inner wall can be prevented or reduced.

The present invention also provides another substrate cleaning apparatus comprising: the above-described substrate processing unit; a frame forming a space in which the substrate processing unit is housed; and a gas supply means for supplying a clean gas to said space.

This can prevent or reduce secondary contamination of a substrate, providing a high-quality processed substrate.

The substrate holder is preferably provided with a holder suction section for sucking in the processing fluid.

This can prevent the fluid from remaining on the substrate holder, thereby preventing or reducing secondary contamination of a substrate via rollers.

The substrate holder preferably comprises a plurality of rollers for bringing into contact with an edge of the substrate to rotate the substrate, said rollers being movable in the radial direction of the substrate.

Such rollers can each apply a force on a substrate in a direction toward the center of the substrate. This can enhance the positional stability of the rotation center of the substrate, thus enhancing the rotational accuracy of the substrate.

In a preferred aspect of the substrate cleaning apparatus of the present invention, the substrate processing unit includes a substrate holder for rotatably holding the substrate and processes the substrate by supplying a fluid to the substrate while rotating the substrate, and the substrate holder is provided with a holder suction section for sucking in the fluid.

By thus preventing the fluid from remaining on the substrate holder, secondary contamination of a substrate via rollers can be prevented or reduced.

In a preferred aspect of the substrate cleaning apparatus of the present invention, the substrate processing unit includes: a substrate holder for horizontally holding and rotating a substrate; a gas supply nozzle, disposed above and below the substrate held by the substrate holder, for supplying a gas to the substrate; a liquid supply nozzle, disposed above and below the substrate held by the substrate holder, for supplying a liquid to the substrate; and a movement mechanism for moving the gas supply nozzle and the liquid supply nozzle from the center to the periphery of the substrate, said liquid supply nozzle being disposed at an outer position than the gas supply nozzle in the radial direction of the substrate.

With this structure, a drying gas can be jetted to a substrate while supplying a liquid from the liquid supply nozzle to the substrate and protecting the upper and lower surfaces of the substrate with the liquid film. Thus, even when drying a patterned substrate in which hydrophilic portions and hydrophobic portions are co-present in the surface, the hydrophilic portions and the hydrophobic portions can be dried simultaneously over the entire substrate surface. This can reduce the formation of watermarks on the substrate.

In a preferred aspect of the substrate cleaning apparatus of the present invention, at least one fluid supply port and at least one suction port, spaced away from each other and located in the vicinity of the rotating substrate, are provided in the substrate processing unit, and a processing fluid is supplied from the fluid supply port to the substrate while the processing fluid adhering to the substrate is sucked into the fluid suction port.

Thus, spattering of the fluid from the surface of a substrate can be prevented and the fluid can be used efficiently, thereby reducing the amount of the fluid used. In addition, secondary contamination of a substrate can be prevented or reduced.

In a preferred aspect of the substrate cleaning apparatus of the present invention, the substrate processing unit includes a substrate holder for holding and rotating the substrate, and the substrate holder comprises a plurality of rollers for bringing into contact with an edge of the substrate to rotate the substrate, said rollers being movable in the radial direction of the substrate.

Such rollers can each apply a force on a substrate in a direction toward the center of the substrate. This can enhance the positional stability of the rotation center of the substrate, thus enhancing the rotational accuracy of the substrate.

### BRIEF DESCRIPTION OF DRAWINGS

FIG. 1 is an external view showing an embodiment of a substrate cleaning apparatus according to the present invention;

FIG. 2 is a plan view of the substrate cleaning apparatus of FIG. 1;

FIG. 3 is a plan view of a frame of the substrate cleaning apparatus of FIG. 1;

FIG. 4 is a side view (as viewed from the direction of arrow A shown in FIG. 3) of the frame of the substrate cleaning apparatus of FIG. 1;

FIG. 5 is a rear view (as viewed from the direction of arrow B shown in FIG. 3) of the frame of the substrate cleaning apparatus of FIG. 1;

FIG. 6 is a plan view showing the flow of air in the substrate cleaning apparatus according to the present invention;

FIG. 7 is a side view showing the flow of air in the substrate cleaning apparatus according to the present invention;

FIG. 8 is a plan view showing the flow of air and air pressures in the substrate cleaning apparatus according to the present invention;

FIG. 9 is a diagram showing an embodiment of a system of a processing liquid supply apparatus of the substrate cleaning apparatus according to the present invention;

FIG. 10 is a diagram showing the flow of supply of a processing liquid in the substrate cleaning apparatus according to the present invention;

FIG. 11 is a diagram showing the flow of supply of the processing liquid in the substrate cleaning apparatus according to the present invention;

FIG. 12 is a diagram showing an embodiment of a substrate processing unit of the substrate cleaning apparatus according to the present invention;

FIGS. 13A through 13C are diagrams showing the construction of the etching section of the substrate processing unit;

FIGS. 14A and 14B are diagrams showing an embodiment of a drying mechanism of the substrate processing unit of the substrate cleaning apparatus according to the present invention;

FIG. 15 is a diagram showing another embodiment of a drying mechanism of the substrate processing unit of the substrate cleaning apparatus according to the present invention;

FIG. 16 is a diagram showing another embodiment of a substrate cleaning apparatus according to the present invention;

FIG. 17 is a diagram showing a top panel of a chamber of the substrate processing unit according to the embodiment of FIG. 16;

FIG. 18 is a cross-sectional diagram showing the construction of the substrate processing unit according to the embodiment of FIG. 16;

FIG. 19 is a diagram showing the construction of the substrate holder of the substrate processing unit of FIG. 18;

FIG. 20 is a cross-sectional diagram showing the construction of the substrate holder of the substrate processing unit of FIG. 18;

FIG. 21 is a cross-sectional diagram showing the detail of the clamp portion of the substrate holder of FIG. 20;

FIGS. 22A through 22C are diagrams showing the detail of the roller cover of the substrate holder of FIG. 20;

FIG. 23 is a diagram showing the state of the substrate processing unit of FIG. 18 during bevel etching;

FIGS. 24A through 24C are diagrams showing the operation of a gas jet nozzle in the substrate processing unit of FIG. 18;

FIGS. 25A and 25B are diagrams illustrating the operation of an inner wall cleaning nozzle in the substrate processing unit of FIG. 18;

FIG. 26 is a diagram showing an airflow created in a chamber of the substrate processing unit of FIG. 18;

FIG. 27 is a diagram showing a variation of an air intake of the substrate processing unit of FIG. 18;

FIGS. 28A and 28B are diagrams showing a variation of the substrate processing unit of FIG. 18, illustrating the operation of a roller cover cleaning nozzle;

FIG. 29 is a perspective view schematically showing a substrate processing unit according to another embodiment of the present invention:

FIGS. 30A through 30D are enlarged views of a substrate holder of the substrate processing unit of FIG. 29, FIG. 30A being a plan view, FIG. 30B a cross-sectional view, FIG. 30C a cross-sectional view showing a variation of FIG. 30B, and FIG. 30D a plan view showing a variation of FIG. 30A;

FIGS. 31A through 31D are diagrams illustrating the positional relationship between a gas supply nozzle and a liquid supply nozzle shown in FIG. 29;

FIG. 32 is a plan view of a substrate processing unit according to another embodiment of the present invention;

FIG. 33 is a side view showing the main portion of the substrate processing unit of FIG. 32;

FIG. 34A is an enlarged view of cleaning nozzles shown in FIG. 33, FIG. 34B is a cross-sectional view of a suction port, and FIG. 34C is a cross-sectional view of a supply port;

FIG. 35 is a schematic diagram showing the reciprocation of the cleaning nozzle;

FIG. 36A is a diagram illustrating supply and suction of a fluid (liquid) to and from a substrate, FIG. 36B is a diagram illustrating supply of a fluid (liquid) in a spiral manner, FIG. 36C is a diagram illustrating unstable supply of a fluid (liquid), and FIG. 36D is a diagram illustrating a trace of the reciprocation of supply ports and suction ports;

FIG. 37 is a plan view showing the construction of the main portion of a substrate processing unit according to another embodiment of the present invention;

FIG. 38 is a cross-sectional view of the substrate processing unit shown in FIG. 37; and

FIG. 39 is block diagram showing the construction of a system of the substrate processing unit shown in FIG. 38.

### BEST MODE FOR CARRYING OUT THE INVENTION

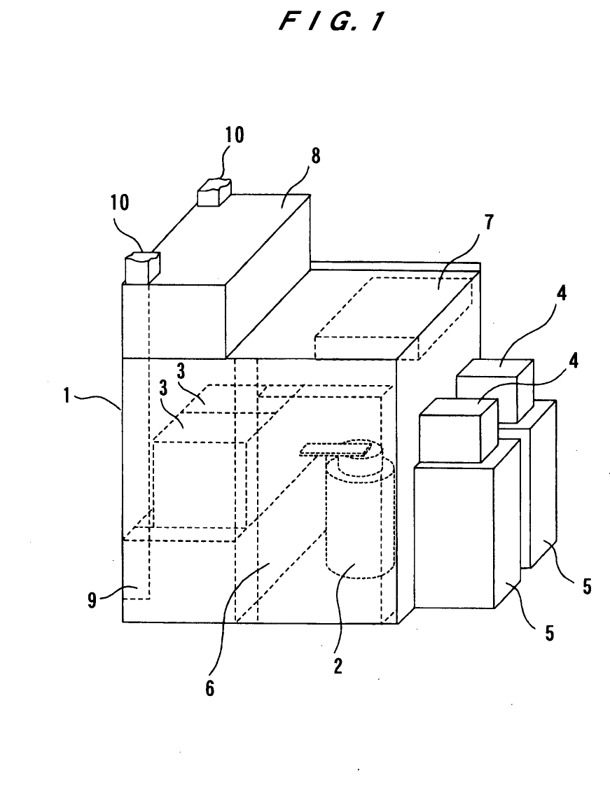

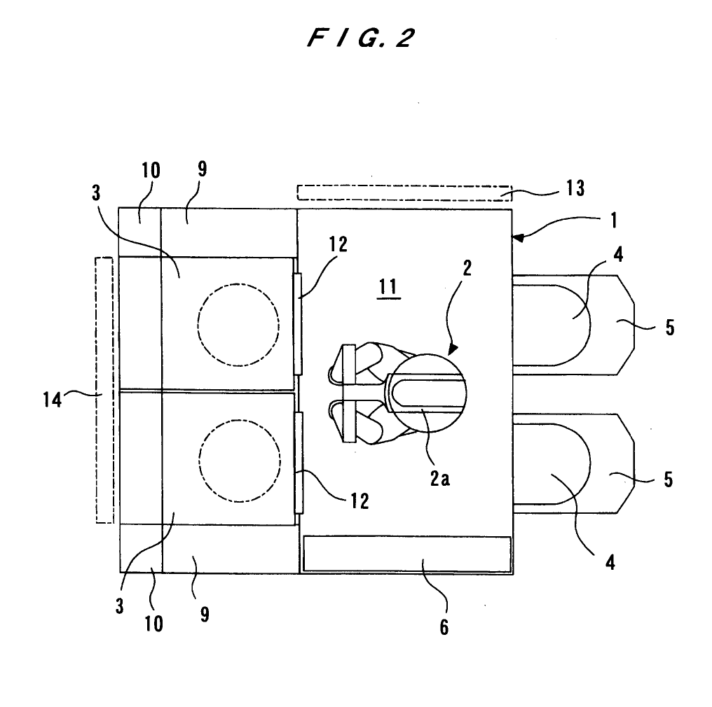

Preferred embodiments of the present invention will now be described with reference to the drawings. FIGS. 1 and 2 are diagrams showing an embodiment of a substrate cleaning apparatus according to the present invention, FIG. 1 showing a schematic perspective view and FIG. 2 showing a schematic plan view. The substrate cleaning apparatus comprises a base-integrated frame 1 in or on which are mounted a fixed transport robot 2 as a substrate transport device for transporting a substrate, substrate processing units 3, 3 for processing the substrate, substrate loading ports 5, 5 for placing substrate-housing cassettes 4, 4 thereon, and a processing liquid supply apparatus 6 for supplying a processing liquid to the substrate processing units 3, 3.

A fan filter unit 7 is mounted on the ceiling of the frame 1, and a control panel 8 is mounted on the top of the frame 1. Further, instrumentation sections 9, 9 and ventilation ducts 10, are disposed beside the substrate processing units 3, 3. Dampers 12, 12 are provided between the substrate processing units 3, 3 and a substrate transport chamber 11 in which the fixed transport robot 2 is disposed. A space 13 for a man to enter for maintenance is provided outside the substrate transport chamber 11. Further, a space 14 for a man to enter is provided outside the substrate processing units 3, 3.

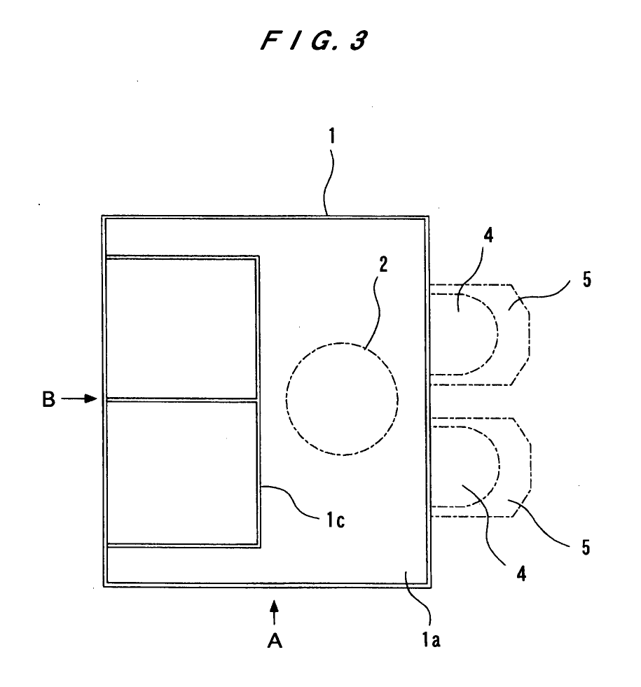

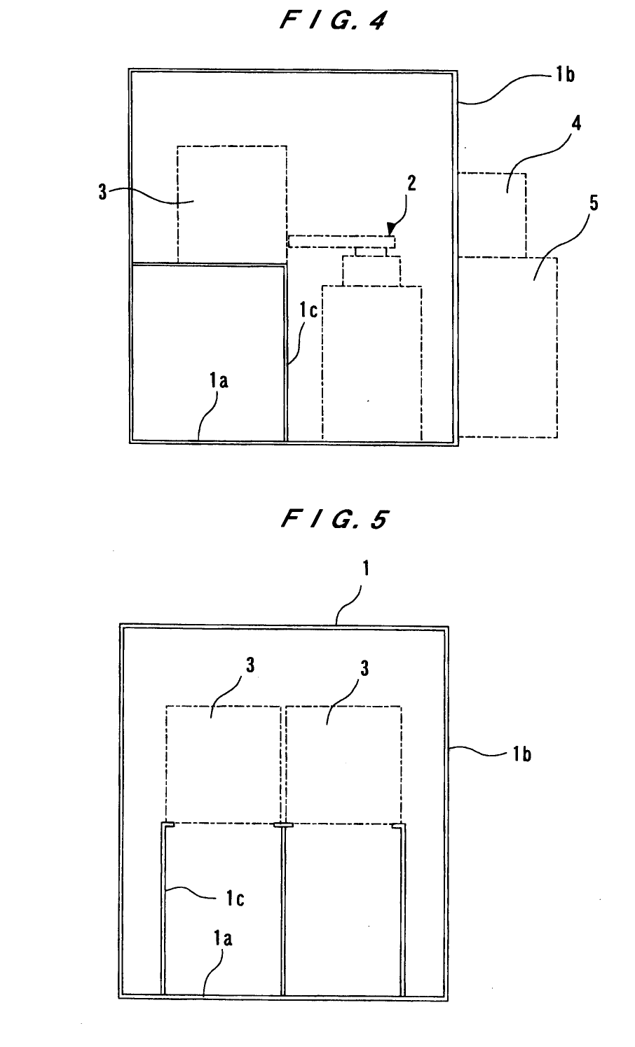

FIGS. 3 through 5 are diagrams showing the construction of the frame 1, FIG. 3 showing a cross-sectional plan view, FIG. 4 showing a cross-sectional side view as viewed from the direction of arrow A shown in FIG. 3, and FIG. 5 showing a cross-sectional side view as viewed from the direction of arrow B shown in FIG. 3. The frame 1 is a base-integrated frame with a base portion 1a integrated with a frame portion 1b, has a cubic shape with square plan and side views, and includes a frame 1c, mounted on the base 1a, for placing thereon the substrate processing units 3, 3. The transport robot 2 is mounted on the base 1a, the substrate processing units 3, 3 are mounted on the frame 1c, and the substrate loading ports 5, 5 are mounted externally on the frame 1b of the base-integrated frame 1 having the above construction. The substrate loading ports 5, 5 and the substrate processing units 3, 3 are disposed parallel to each other with the substrate transport chamber 11 interposed therebetween.

The substrate cleaning apparatus is capable of mounting in the base-integrated frame 1a plurality of substrate processing units 3 (two units are illustrated in the Figure) necessary for processing of a substrate, and the outer sizes and the mounting sizes of substrate processing units 3 are unified. Thus, by freely combining a plurality of substrate processing units 3, the present substrate cleaning apparatus can deal with a plurality of processes. The instrumentation sections 9, 9 are disposed beside the substrate processing units 3, 3.

This substrate cleaning apparatus, because of its integral structure, can be transported as it is without separation. Also because of the integral structure, the position of the transport robot 2, which acts as a substrate transport system, can be maintained. This can eliminate the need for positioning of the substrate transport system upon installation of the apparatus, thus considerably shortening the start-up time of the apparatus. Further, with the provision of the processing liquid supply apparatus 6 and the control panel (power supply) 8, the installation area of the overall system can be minimized. In addition, with the provision of the enterable spaces 13, 14 outside the substrate transport chamber 11 and the substrate processing units 3, 3, their maintenance can be performed with no difficulty. In particular, maintenance of the substrate processing units 3, 3 can be performed in the space 14, i.e., from the backside of the apparatus. The shape, size and configuration of each substrate processing unit 3 are so designed that its interior is accessible from the backside of the apparatus.

Ordinary maintenance of the transport robot 2 is performed by access from the space 13. When replacement of a part is necessary, it is taken from the space 13. In that case, a maintenance space will be needed. The interior of each substrate processing unit 3 is made all accessible from the space 14 on the backside of the apparatus so that a maintenance space can be minimized in performing ordinary maintenance. The processing liquid supply apparatus 6 is easily accessible from the left side of the apparatus, so that replacement of a part can be performed with ease upon maintenance of the apparatus 6. Further, the instrumentation section 9 is easily accessible from both sides of the apparatus, so that maintenance of the section 9 and replacement of an instrument can be performed with ease. Thus, the interior of the present substrate cleaning apparatus is all accessible directly from the outside of the apparatus. There is, therefore, no such defect that maintenance cannot be performed without moving a part of an instrument, and maintenance of the apparatus can be performed very easily.

In order to minimize the generation of particles, the substrate cleaning apparatus employs as a substrate transport device the fixed transport robot 2 having no travel axis. The transport robot 2 has a plurality of hands 2a which are adapted for a dry substrate and operate independently, and is capable of moving the hands 2a backward and forward, right and left, and up and down, and swiveling the hands 2a. The transport robot 2 can therefore transport and transfer a substrate between the substrate-housing cassettes 4, 4 and the opposite substrate processing units 3, 3 via openable/closable shutters (4 shutters, not shown) provided in the frame portion 1b opposite to the substrate-housing cassettes 4, 4 and in the partition walls of the substrate processing units 3, 3. Since all the substrate processing units 3, 3 are disposed opposite to the substrate-housing cassettes 4, 4, there is no need for extra transfer of a substrate, and transport of a substrate can be performed by a minimum operation of the fixed transport robot 2.

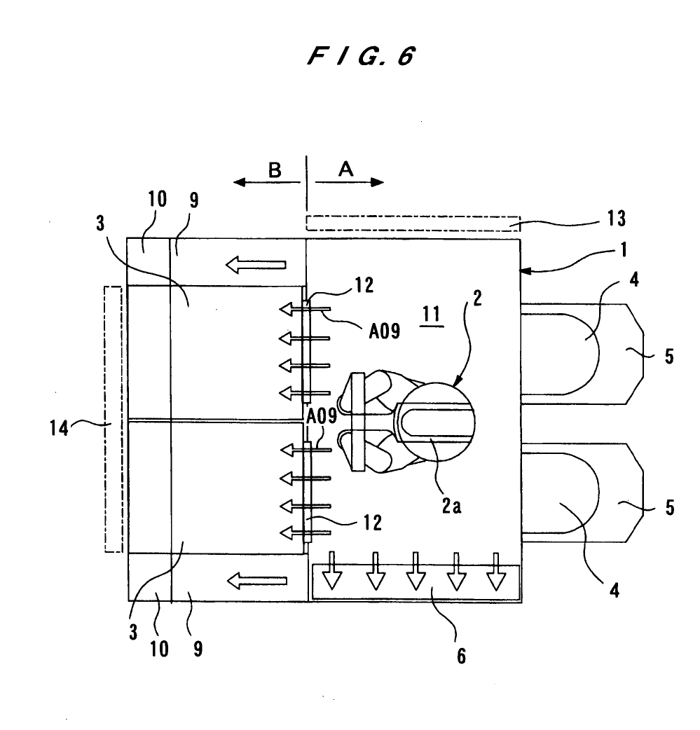

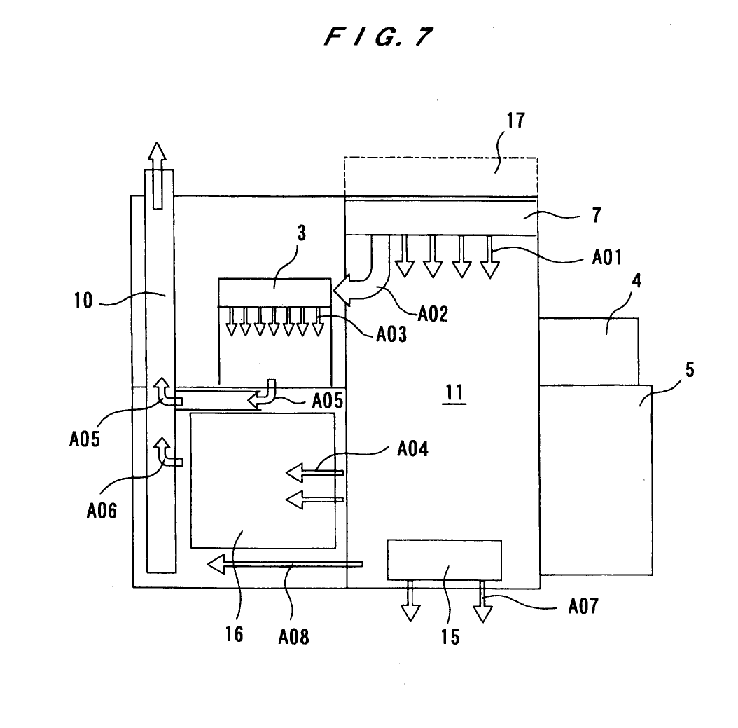

FIGS. 6 and 7 are diagrams showing the flow of air (airflow) in the substrate cleaning apparatus of the present invention. The substrate cleaning apparatus is usually installed in a clean room. Air, which has been taken in from the clean room, passes through a fan filter unit 7 where particles, etc. are removed, and is guided into the apparatus. In the apparatus, the air flows from the loading area, shown by the arrow A in FIG. 6, to the processing area shown by the arrow B. As shown in FIG. 7, part of the air passing through the fan filter unit 7 creates a downward airflow A01 which flows down in the substrate transport chamber 11, while the other air A02 is guided to the ceiling of the substrate processing unit 3, and creates a dispersed downward airflow A03 which flows down in the substrate processing unit 3 from the ceiling. It is possible to install a chemical filter 17 before the fan filter unit 7. The instrumentation sections 9, 9 are disposed on both sides of the substrate processing units 3, 3.

As shown in FIG. 6, part of the air in the substrate transport chamber 11 is guided in the form of airflow A09 into the substrate processing unit 3 via the damper 12, provided between the substrate transport chamber 11 and the substrate processing unit 3, which is capable of adjusting the flow rate. Under the substrate processing unit 3 is disposed a valve box 16 in which are housed various valves, for supplying a processing liquid, of the instrumentation section 9. As shown in FIG. 7, part of the air in the substrate transport chamber 11 flows in the form of airflow A04 into the valve box 16. The frame 1, the substrate processing unit 3, the instrumentation section 9 and the processing liquid supply apparatus 6 are partitioned by walls, and the pressures in the divided areas are each adjusted to a predetermined pressure.

Since various processing or cleaning liquids are used in the substrate processing unit 3, the internal air is contaminated, e.g., with their mist. The air in the substrate processing unit 3 is therefore discharged as discharge air A05 from the bottom of the substrate processing unit 3 through a ventilation duct 10. The air in the valve box 16 is also possibly contaminated, e.g., with a mist, and is therefore discharged as discharge air A06 through the ventilation duct 10. As shown in FIG. 7, part of the air in the substrate transport chamber 11 is discharged as discharge air A07 out of the apparatus through a damper 15. Further, part of the air in the substrate transport chamber 11 flows in the form of airflow A08 through the space under the valve box 16, and is discharged through the ventilation duct. The temperature and the humidity of the air may be adjusted to predetermined values. It is also possible to supply an inert gas (e.g., N₂ gas) instead of air. This can prevent deterioration of a substrate to be processed during processing or during transportation.

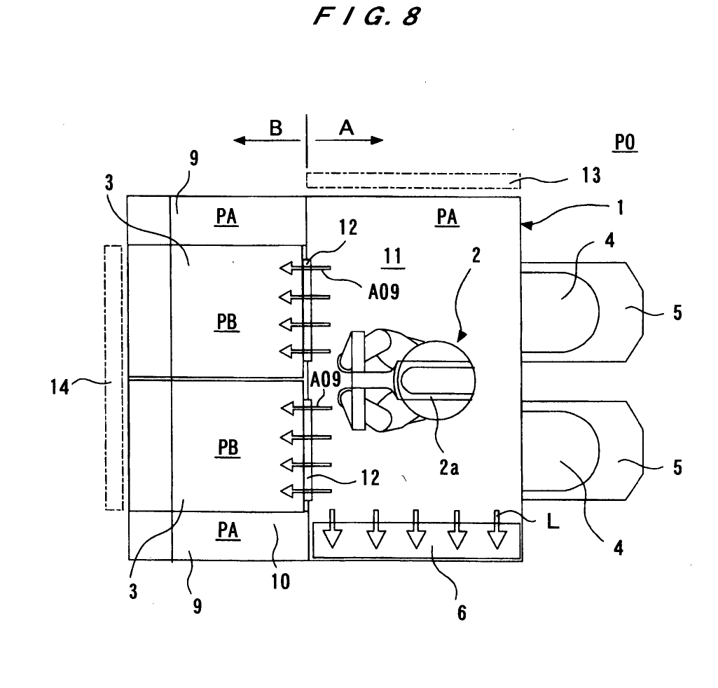

FIG. 8 is a diagram showing air pressures in the substrate cleaning apparatus of the present invention and the atmospheric pressure outside the apparatus. Air pressures are regulated so that the following relation is maintained: PA>PO>PB, wherein PO represents air pressure (atmospheric pressure) outside the apparatus, PA represents air pressure in the substrate transport chamber 11, and PB represents air pressure in the substrate processing unit 3. This makes it possible to keep the atmosphere in the substrate transport chamber 11 clean (prevent the air outside the apparatus from flowing into the chamber), so that a substrate, which has undergone processing in the substrate processing unit 3, can be housed in a clean state in the substrate-housing cassette 4 by the hands 2a of the transport robot 2.

In the substrate cleaning apparatus of the present invention, the processing liquid supply apparatus 6 has a plurality of supply tanks for each substrate processing unit 3. All the processing liquids are supplied from the supply tanks in a pressure feeding manner with an inert gas (e.g., N₂ gas). Accordingly, unlike supply, e.g., by pumping, there is no pulsing on supply nor generation of particles, enabling stable supply of processing liquid. Two or more types of processing liquids can be supplied to each of a plurality of substrate processing units 3, 3 (two units are illustrated in the Figures).

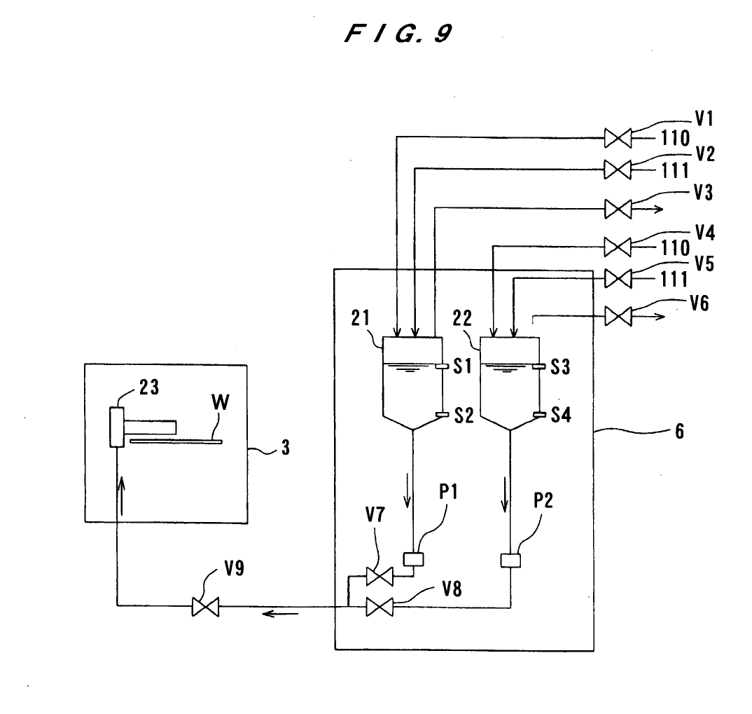

Further, a plurality of supply tanks are provided for each processing liquid, and the processing liquid is supplied alternately from the supply tanks. FIG. 9 shows an embodiment of a system of a processing liquid supply apparatus for supplying one type of processing liquid to one substrate processing apparatus. As illustrated in FIG. 9, the system includes a plurality of supply tanks 21, 22 (two tanks are illustrated in the Figure) for the one type of processing liquid. To the supply tanks 21, 22 are respectively connected processing liquid supply valves V1, V4 for supplying the processing liquid, inert gas supply valves V2, V5 for supplying an inert gas, and depressurization valves V3, V6.

Valves V7, V8 are also connected to the supply tanks 21, 22, respectively, so that by switching between the valves V7, V8, the processing liquid can be supplied to the substrate processing unit 3 alternately from the supply tanks 21, 22. The substrate processing unit 3 is provided with a valve V9 and a processing liquid jet nozzle 23 for jetting the processing liquid, so that the processing liquid, supplied via the valve V9, can be jetted to a substrate W to be processed. The valves V1 to V9 are disposed in the above-described valve box 16 (see FIG. 7). The supply tank 21 is provided with an upper limit sensor S1 and a lower limit sensor S2, and the supply tank 22 is also provided with an upper limit sensor S3 and a lower limit sensor S4. The processing liquid supply apparatus 6 includes a pressure sensor P1 for detecting the pressure of the processing liquid discharged from the supply tank 21 and a pressure sensor P2 for detecting the pressure of the processing liquid discharged from the supply tank 22.

The supply of the processing liquid from the supply tank 21, 22 is performed by using the pressure of the inert gas, supplied via the inert gas supply valve V2, V5, as a power. The pressure of the processing liquid from the supply tank 21, 22 is monitored by the pressure sensor P1, P2; and when the pressure becomes higher than necessary, the depressurization valve V3, V6 is opened to degas in the supply tank 21, 22.

FIGS. 10 and 11 are diagrams showing the flow of supply of the processing liquid in the processing liquid supply apparatus. First, in step ST1 of FIG. 10, a determination is made as to whether the lower limit sensor S2 of the supply tank 21 is “on”. If the determination is “no” (the level of processing liquid is lower than the lower limit), a determination is then made as to whether the lower limit sensor S4 of the supply tank 22 is “on” or not (step ST2). Regardless of whether the determination is “no” or “yes”, i.e., in both cases, the process proceeds to step 21 of FIG. 11. On the other hand, if the determination in step ST1 is “yes”, a determination is then made as to whether the limit sensor S4 of the supply tank 22 is “on” (step ST3). If the determination is “no”, the process proceeds to step ST24 of FIG. 11, whereas if the determination is yes the process proceeds to step ST27 of FIG. 11.

In step ST21 of FIG. 11, the depressurization valve V3 is closed, and then the processing liquid L is supplied to the supply tank 21 while the inert gas supply valve V2 is opened to supply the inert gas to the supply tank 21, and the valve V7 and the valve V9 are opened to supply the processing liquid to the substrate processing unit 3 (step ST22). Subsequently, a determination is made as to whether the lower limit sensor S2 of the supply tank 21 is “on” (step ST23). If the determination is “yes”, then the depressurization valve V6 is closed to stop the depressurization of the supply tank 22 (step ST24). Subsequently, the inert gas supply valve V5 and the valve V8 are opened to supply the processing liquid L in the supply tank 22 to the substrate processing unit 31 (step ST25).

Subsequently, the inert gas supply valve V2 and the valve V7 are closed to stop the supply of the processing liquid L from the supply tank 21 (step ST26). Subsequently, the depressurization valve V3 is opened to depressurize the supply tank 21 (step ST27). Subsequently, the processing liquid supply valve V1 is opened to replenish the supply tank 21 with the processing liquid L (step ST28). Subsequently, a determination is made as to whether the upper limit sensor S1 of the supply tank 21 is “on” (step ST29). If the determination is “yes”, then the processing liquid supply valve V1 is closed to stop replenishing the supply tank 21 with processing liquid to the supply tank 21 (step ST30).

Subsequently, a determination is made as to whether the lower limit sensor 24 of the supply tank 22 is “on” (step ST31). If the determination is “no”, the sensor turning to “on” is awaited. On the other hand, if the determination is “yes”, the process proceeds to the above step ST21.

If the lower limit sensor S2 of the supply tank 21 is not “on” in the above step ST23, a determination is then made as to whether the lower limit sensor 24 of the supply tank 22 is “on” (step ST32). If the determination is “no”, the process returns to the above step ST23. On the other hand, if the determination is “yes”, then the depressurization valve V6 is opened to depressurize the supply tank 22. Subsequently, the processing liquid supply valve V4 is opened to replenish the supply tank 22 with the processing liquid (step ST34). Subsequently, a determination is made as to whether the upper limit sensor S3 of the supply tank 22 is “on” (step ST35). If the determination is “no”, the sensor turning to “on” is awaited. On the other hand, if the determination is “yes”, then the processing liquid supply valve V4 is closed to stop replenishing the supply tank 22 with the processing liquid, and the process proceeds to the above step ST23.

As described above, the processing liquid supply apparatus includes a plurality of tanks (two tanks are illustrated in the Figure). A processing liquid is supplied from either one of the supply tanks 21, 22, for example, the supply tank 21 to the substrate processing unit 3. When the processing liquid in the supply tank 21 has run out, the tank is switched to the supply tank 22 by valve switching. While supplying the processing liquid from the supply tank 22, replenishment of the supply tank 21 with the processing liquid is carried out. By thus supplying the processing liquid to the substrate processing unit 3 alternately from the two supply tanks 21, 22, continuous supply of the processing liquid becomes possible. The alternate use of the two supply tanks 21, 22 makes it possible to continuously process a substrate and to minimize the volume of the supply tanks 21, 22. The processing liquid supply apparatus can therefore be considerably downsized, thus minimizing the influence of its installation in the substrate cleaning apparatus on the footprint of the apparatus.

At least one, preferably all of the plurality of substrate processing units mounted in the substrate cleaning apparatus, is a substrate process unit capable of completing a process by itself, i.e., a unit having a post-processing drying function. For example, the substrate processing unit is provided with a plurality of independent nozzles, disposed above and below a substrate, for jetting an inert gas (e.g., N₂ gas) to front and back surfaces of the substrate. After completion of wet processing of the substrate, such as cleaning of the both surfaces, bevel etching, or scrubbing of the back surface, the inert gas is jetted from the nozzles to the both surfaces of the substrate to dry the substrate. The use of such a substrate processing unit enables the use of a substrate transport device adapted exclusively for a dry substrate, which can be a low-cost device without the need of measures for a wet substrate. For example, a fixed robot having a plurality of dry hands can be sufficiently used.

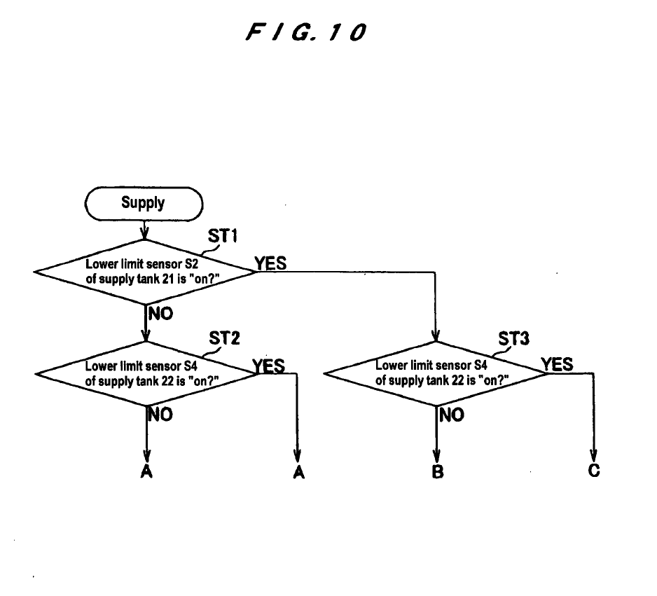

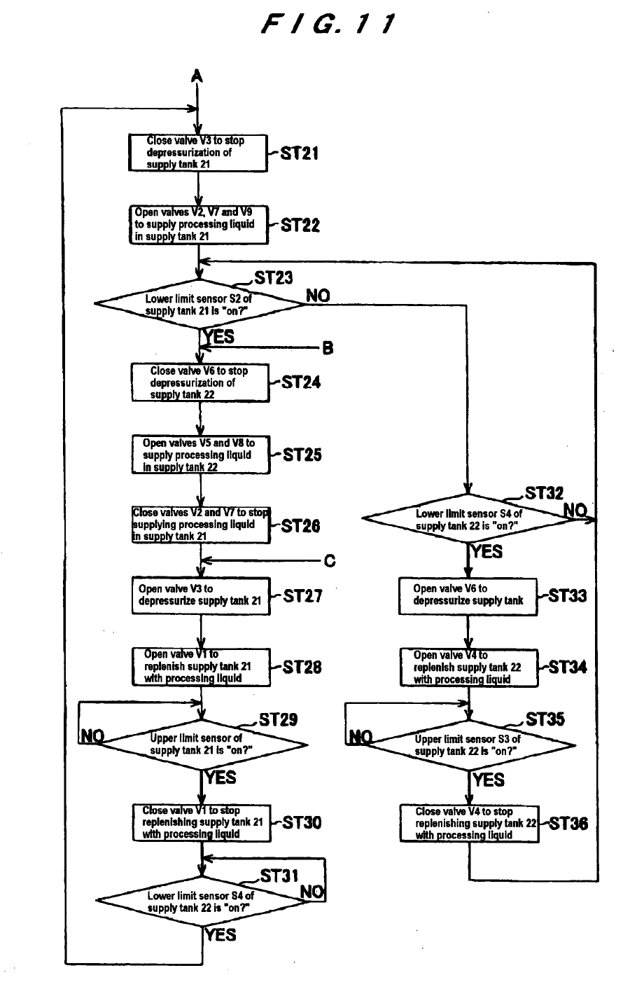

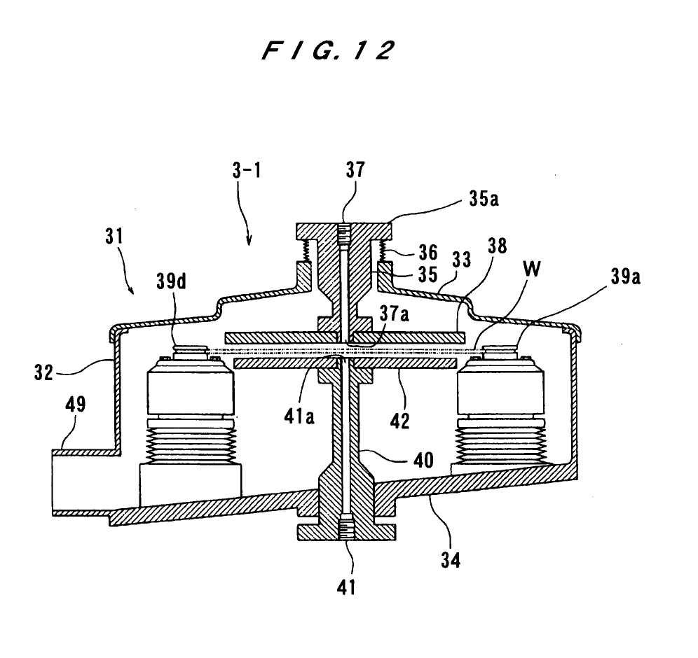

FIG. 12 is a cross-sectional diagram showing an embodiment of a substrate processing unit 3-1. The substrate processing unit 3-1 includes a chamber 31. The chamber 31 comprises a cylindrical chamber body 32 and a chamber cover 33 for covering the top of the chamber body 32. The cylindrical chamber body 32 is mounted vertically, and its lower end is closed up with a bottom portion 34. The chamber cover 33 has the shape of an inverted bowl, covering the top of the cylindrical chamber body 32. The upper end portion of the chamber body 32 makes tight contact with a peripheral portion of the chamber cover 33 so that the interior of the chamber 31 can be shielded from the outside air.

The bottom portion 34 is slightly inclined with respect to a horizontal plane. A gas/water discharge pipe 49 both for gas discharge and for water discharge is connected to the chamber body 32 at its junction with the lowermost portion of the inclined bottom portion 34.

An opening is formed in the center of the chamber cover 33, and an upper shaft 35, vertically passing through the opening, is provided. The upper shaft 35 has, at its upper end, a disk-shaped flange portion 35a. The opening of the chamber cover 33 and the flange portion 35a are seal-connected by a bellows-like flexible joint 36. The upper shaft 35 centrally has a conduit 37 that vertically penetrates the upper shaft 35. The conduit 37 is to supply a gas for purging oxygen, such as nitrogen gas, or ultrapure water for rinsing to a substrate surface. The front end of the conduit 37 forms a nozzle 37a for a substrate W.

The chamber cover 33 and the upper shaft 35 are coupled by a not-shown coupling member such that their relative position in the vertical direction is adjustable. Thus, the coupling member is provided with a not-shown drive device for moving the upper shaft 35 relative to the chamber cover 33 so as to adjust their relative position. The provision of the flexible joint 36 can deal with a change in the relative position between the chamber cover 33 and the upper shaft 35.

An upper disk 38, which is a circular flat plate, is mounted horizontally to the lower end of the upper shaft 35. The upper disk 38 is disposed such that its lower surface faces a surface of a circular substrate W to be processed and lies parallel to the substrate surface. The gap between the lower surface of the upper disk 38 and the surface of the substrate W is made as small as possible. The gap is arbitrarily adjusted, e.g., within the range of 0.5 to 20 mm. The gap is preferably adjusted to about 0.8 to 10 mm, more preferably about 1 to 4 mm so that nitrogen gas or ultrapure water, which has been supplied through the conduit 37, can flow uniformly over the surface of the substrate W. The gap adjustment can achieve the object of processing or protecting the substrate W with a relatively small amount of fluid. The gap adjustment can be performed by adjusting the relative position between the upper shaft 35 and the chamber cover 33.

The bottom portion 34 has not-shown 6 openings. Six rollers 39a to 39f are mounted vertically which pass through the openings and make contact with the peripheral edge of the substrate W to support the substrate W horizontally. The 6 rollers 39a to 39f, by their relations about their own axes, rotate the substrate W. It suffices if the substrate W can be rotated at a constant low speed while keeping it in a horizontal position, with the maximum rotational speed being 300 min⁻¹.

A chamber lower shaft 40, located below the back surface of the substrate W supported by the rollers 39a to 39f, is mounted vertically on the bottom portion 34. The chamber lower shaft 40 centrally has a conduit 41 which vertically penetrates the shaft 41 and whose lower end forms a nozzle 41a.

A lower disk 42, which is a circular flat plate, is mounted to the upper end of the chamber lower shaft 40 such that the upper surface of the lower disk 38 faces the back surface of the substrate W supported by the rollers 39a to 39f and lies parallel to the back surface of the substrate W. As with the gap between the upper disk 38 and the substrate W, the gap between the lower disk 42 and the substrate W preferably is as small as possible, and is appropriately adjusted, e.g., within the range of 0.5 to 20 mm. The gap is preferably adjusted to about 1 to 4 mm so that nitrogen gas or ultrapure water, which has been supplied through the conduit 41, can flow along the gap between the back surface of the substrate W and the lower disk 42. The gap adjustment makes it possible to process or protect the substrate with a relatively small amount of fluid.

The construction of an etching section for etching a peripheral bevel portion of the substrate W in the substrate processing unit 3-1 having the above construction will now be described with reference to FIGS. 13A through 13C. FIG. 13A is a perspective view showing the relationship between the etching section 45 and the substrate W supported by the rollers 39a to 39f, FIG. 13B is a side view of the etching section 45, and FIG. 13C is a plan view of the etching section.

As shown in FIG. 13B, the etching section 45 is a U-shaped member configured to sandwich a peripheral portion of the substrate W with gaps on front surface and back surface sides of the substrate W. To an upper cantilever portion 45a of the etching section 45 are connected, in upstream order along the direction of rotation of the substrate W, a gas introduction pipe 46a for a gas for drying the substrate W, such as nitrogen gas, an ultrapure water introduction pipe 46b for rinsing for cleaning the substrate W, and a chemical introduction pipe 46 for a first liquid chemical, such as hydrofluoric acid, for etching a metal film formed on the bevel portion of the substrate W. The introduction pipes penetrate the upper cantilever portion 45a and supply nitrogen gas, ultrapure water and the liquid chemical to the bevel portion of the substrate W.

The liquid chemical to be supplied from the chemical introduction pipe 46c is a mineral acid or an organic acid, as an etching liquid, and/or an oxidizing agent. Examples of the mineral acid include hydrofluoric acid (HF), hydrochloric acid (HCl), nitric acid (HNO₃), sulfuric acid (H₂SO₄), etc., and the liquid chemical may contain at least one of these mineral acids. Examples of the organic acid include acetic acid, formic acid, oxalic acid, etc., and the liquid chemical may contain at least one of these organic acids. Examples of the oxidizing agent include a hydrogen peroxide (H₂O₂) solution, ozone (O₃) water, etc., and the liquid chemical may contain at least one of these agents.

A solenoid valve SV1, which is an on-off valve for supplying an acid, and a solenoid valve SV2, which is an on-off valve for supplying an oxidizing agent, are disposed in parallel upstream of the chemical introduction pipe 46c. A conduit for supplying the acid via the solenoid valve SV1 and a conduit for supplying the oxidizing agent via the solenoid valve SV2 merge into the chemical introduction pipe 46c. The solenoid valve SV1 and the solenoid valve SV2 are on-off controlled by a controller 50.

The controller 50 controls the on-off time and the on-off order of the solenoid valve SV1 and the solenoid valve SV2. The type of the acid and its concentration are appropriately selected depending on the type of a metal film to be processed. The order of supply of the acid and the oxidizing agent to the etching section 45 and the respective supply time are set by the controller 50 so that the acid and the oxidizing agent can be supplied alternately under arbitrary conditions. The controller 50 can alternatively supply the acid and the oxidizing agent simultaneously as the mixture thereof. It is possible to use an adjustment valve, which can adjust the flow rate of the acid or the oxidizing agent, instead of the solenoid valve which can only fully open and close. The use of such an adjustment valve can prepare a mixture of the acid and the oxidizing agent at an arbitrary mixing ratio.

Ultrapure water for cleaning is supplied from the ultrapure introduction pipe 46b. An inert gas (N₂ gas or Ar gas) for drying is supplied from the gas introduction pipe. A water discharge pipe 47, penetrating a lower cantilever portion 45c of the U-shaped etching section 45 from its inside, for discharging the waste of the liquid chemical and ultrapure water out of the chamber 31 is connected to the lower cantilever portion 45c. An air cylinder 48 is provided outside the U-shaped etching section 45. The air cylinder 48 moves, via the shaft, the etching section 45 in a direction closer to the substrate W and in a direction away from the substrate W (the direction A shown in FIGS. 13B and 13C). The etching section 45 is thus retreatable on carry in and out of the substrate W.

After etching of the bevel portion of the substrate W, ultrapure water for cleaning is supplied through the conduit 37 and the conduit 41, and jetted from the nozzle 37a and nozzle 41a to the front and back surfaces of the substrate W to clean the surfaces. After the cleaning, the inert gas for drying is supplied to the conduit 37 and the conduit 41, and is jetted from the nozzle 37a and the nozzle 41a to the front and back surfaces of the substrate W to dry the surfaces.

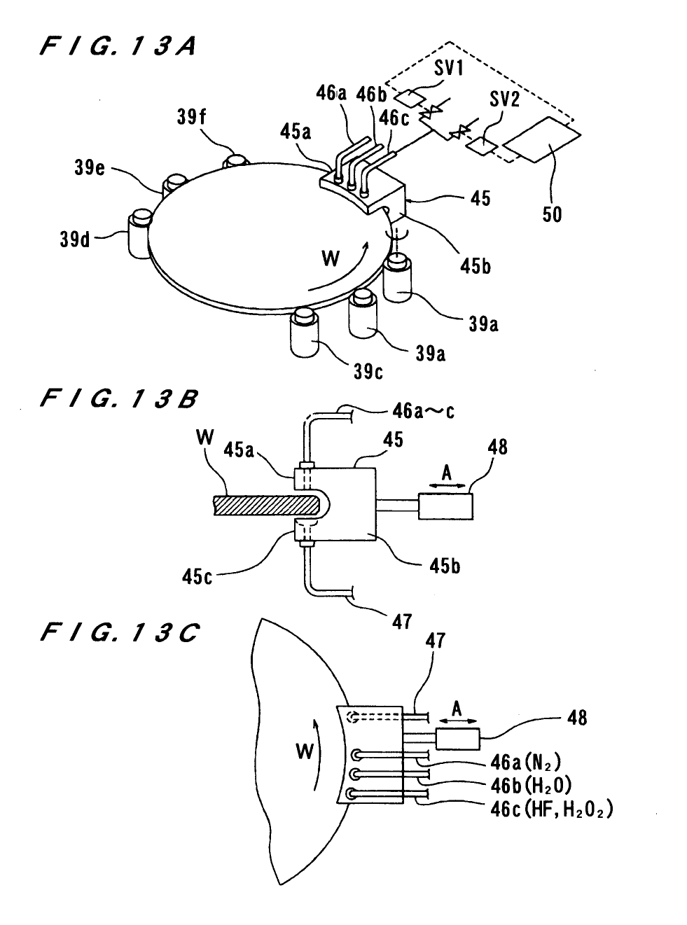

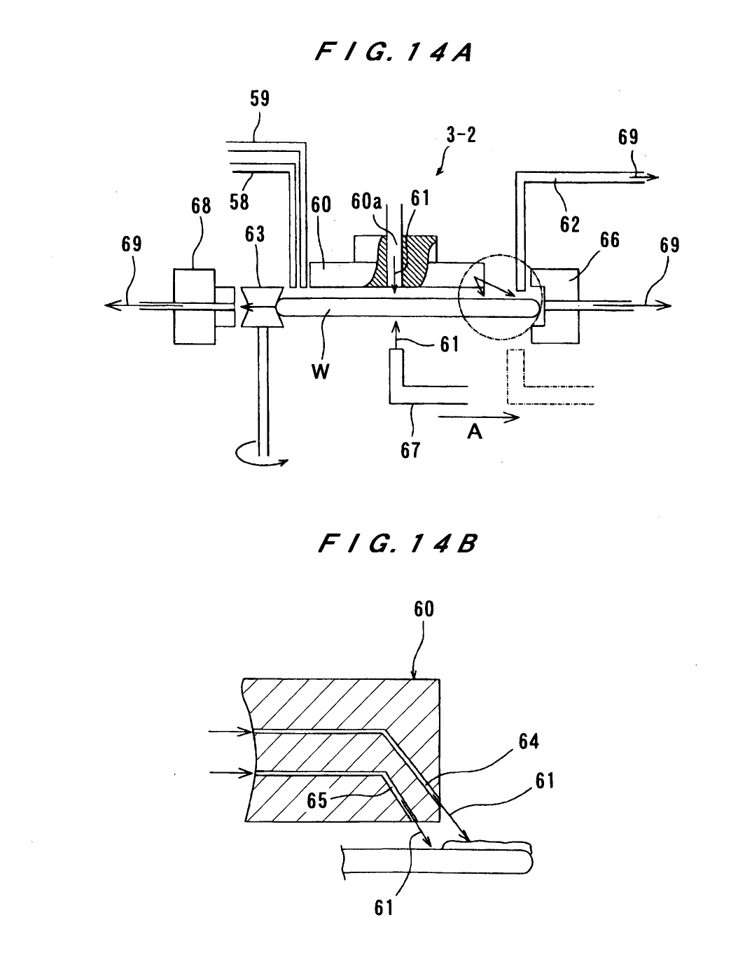

FIGS. 14A and 14B are diagrams showing an embodiment of another substrate processing unit 3-2 for carrying out bevel etching of a substrate W. As shown in FIG. 14A, in carrying out etching of the bevel portion of the substrate W, an upper disk 60 is lowered to a position several mm above the substrate W while rotating the substrate W by rollers 63 which are similar to the rollers 39a to 39f of the substrate processing unit 3-1, and an inert gas (e.g., N₂ gas) 61 is jetted from the central portion 60a of the upper disk 60 toward the periphery of the substrate W, whereby a processing liquid, jetted from an etching nozzle 58, or vapor from the processing liquid is prevented from flowing toward the center of the substrate W. After the etching processing, pure water is supplied from a rinsing nozzle 59 (located at an inner position than the processing liquid supply position) to an edge portion of the rotating substrate W to rinse the peripheral region of the substrate surface. During drying the substrate W, as shown in FIG. 14B, inert gasses 61, 61 are jetted to the rotating substrate W from two jet nozzles 64, 65, provided at peripheral portions of the upper disk 60, and/or from the central portion 60a of the upper disk 60.

The jet nozzle 64 jets the inert gas 61 outwardly toward that peripheral portion of the substrate surface which lies outside the upper disk 60, while the jet nozzle 65 jets the inert gas 61 outwardly toward an inner peripheral portion of the substrate surface. Upon drying of the substrate W, the inert gas 61 is first jetted from the jet nozzle 65 toward the inner peripheral portion of the substrate W, and subsequently the inert gas is jetted from the jet nozzle 64 toward the outer peripheral portion of the substrate W. This can securely remove a liquid remaining on the surface of the substrate, thus drying the substrate surface. The etching section also includes a bevel suction nozzle 62 for sucking in a gas from a peripheral portion of the upper surface of the substrate W, and a suction nozzle 66, having a U-shaped cross section, for sucking in a gas from the side of the peripheral edge of the substrate W. The bevel suction nozzle 62 and the suction nozzle 66 suck in a gas 69 containing the inert gas, a liquid mist, etc. which flows onto the bevel portion of the substrate W during drying. Further, the inert gas 61 is jetted from a jet nozzle 67 to the back surface of the substrate W. The jet nozzle 67 moves from the center to the periphery of the substrate W, as shown by the arrow A, while jetting the inert gas 61. Furthermore, located outside and in the vicinity of the roller 63, a suction nozzle 68 is provided which sucks in the gas 69 containing the inert gas 61 and a liquid mist, flowing onto the surface of the roller 63, thereby drying a surface of the roller 63. It is also possible to provide a plurality of pairs of the jet nozzles 64, 65, the pairs being disposed at regular intervals in the peripheral region of the upper disk 60. Though the jet nozzles 64, 65 are disposed at different radial positions in the same radial direction, it is also possible to dispose them at different radial positions in different radial directions.

Though in FIG. 14A the bevel suction nozzle 62 is disposed apart from the etching nozzle 58 or the rinsing nozzle 59, it is also possible to dispose the bevel suction nozzle 62 close to the nozzle 58 and/or the nozzle 59 to supply a processing liquid and pure water respectively from the etching nozzle 58 and the rinsing nozzle 59 while sucking in the respective liquids by the bevel suction nozzle 62. In that case, if the bevel suction nozzle 62 is located ahead of the nozzle 58, 59 in the direction of rotation of the substrate W, the bevel suction nozzle 62 sucks in a liquid immediately after supply of the liquid from the nozzle 58, 59. On the other hand, if the bevel suction nozzle 62 is located behind of the nozzle 58, 59, the bevel suction nozzle 62 sucks in a liquid after approximately one revolution of the substrate W after supply of the liquid. By thus changing the relative position between the bevel suction nozzle 62 and the etching nozzle 58 or the rinsing nozzle 59, the time of reaction of a liquid with the substrate surface can be adjusted, and the amount of the liquid used or the uniformity of etching or rinsing can be controlled. Movement means for disposing the etching nozzle 58, the rinsing nozzle 59 and the bevel suction nozzle 62 at predetermined positions may be provided. Upon bevel processing of the substrate, processing (cleaning) of the back surface may be carried out simultaneously.

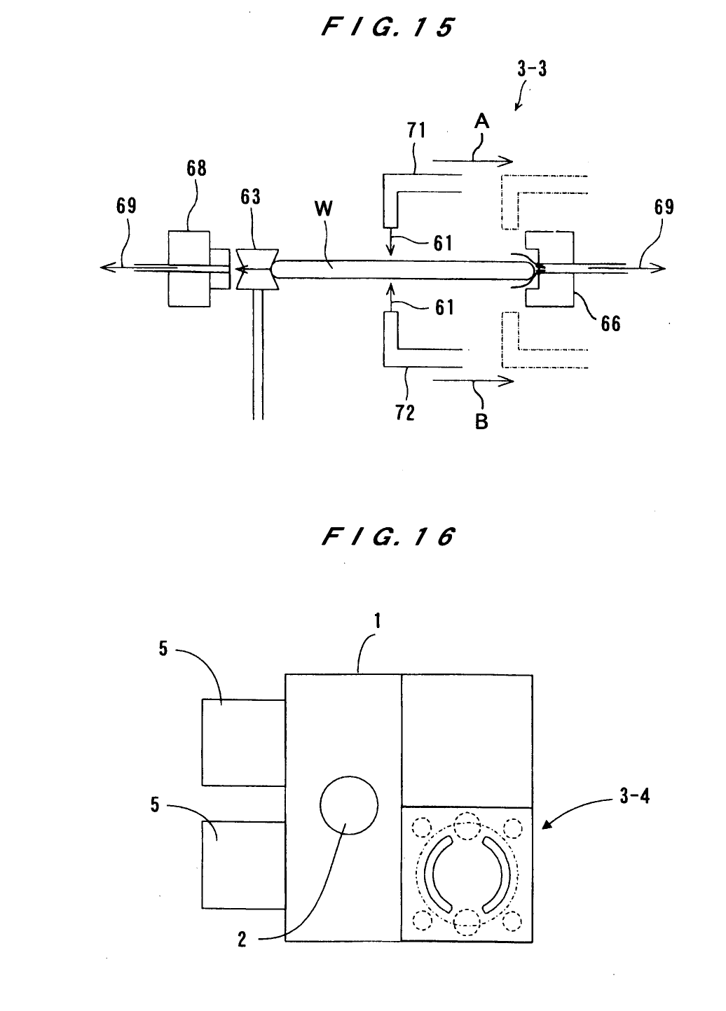

FIG. 15 is a diagram showing an embodiment of a substrate processing unit 3-3 for carrying out drying of a substrate W after carrying out cleaning of both surfaces of the substrate W. As shown in the Figure, the substrate processing unit 3-3 is provided with gas jet nozzles 71, 72 for jetting inert gasses 61, 61 to the front and back surfaces of the substrate W. The inert gasses 61, 61 are jetted from the gas jet nozzles 71, 72 to the front and back surfaces of the substrate W which is being rotated by four rollers 63, which are similar to the rollers 39a to 39f of the substrate processing unit 3-1 for rotating the substrate W, disposed at regular intervals around the substrate W. The gas jet nozzles 71, 72 are moved from the center toward the periphery of the substrate W, as shown by the arrows A, B, so that the substrate W is dried with the drying area expanding from the center to the periphery.

A gas 69 containing an inert gas, a liquid mist, etc. that flows onto the bevel portion of the substrate W upon its drying is sucked into a suction nozzle 66. The gas 69 containing an inert gas, a liquid mist, etc. flowing onto a surface of the roller 63 is also sucked into a suction nozzle 68. When carrying out cleaning of the both surfaces of the substrate W by the substrate processing unit 3-3, scrub cleaning may be carried out by bringing a not-shown cleaning member, such as a PVA sponge, into contact with the both surfaces of the rotating substrate W while supplying a cleaning liquid from a not-shown supply nozzle to the substrate surfaces. Alternatively, cleaning may be carried out by etching the both surfaces of the substrate W, followed by rinsing. Scrub cleaning or etching/rinsing may also be carried out only on one surface (front surface or back surface) of the substrate W.

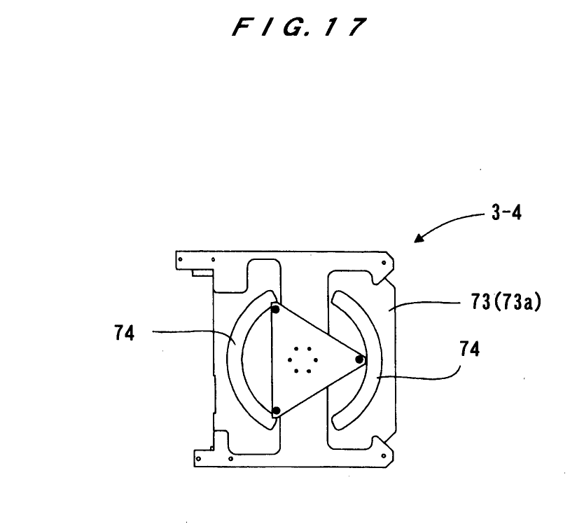

The construction of another substrate processing unit 3-4 for carrying out bevel etching of a substrate W will now be described with reference to FIGS. 16 through 28B. A chamber 73 is box-shaped, having a generally-square cross section. A top panel (lid) 73a is openable and closable and, when the top panel 73a is closed, a liquid is prevented from spattering from the sidewalls to the outside. As shown in FIG. 17, two concentric arc-shaped openings (air intakes) 74 are provided in the top panel 73a, while two air discharge ports 79, disposed on opposite sides of the center of a bottom portion 73b, are provided in the bottom portion 73b. The air discharge ports 79 communicate with the ventilation duct 10. As shown in FIG. 18, the bottom portion 73b is inclined, and a water discharge port 75 is formed on the lower side.

A substrate holder 76 for rotatably holding a substrate W is provided in the chamber 73. The substrate holder 76 includes four rollers 77 for horizontally holding and rotating the substrate W. As shown in FIG. 18, a bellows-like cover member 78 is provided between the lower end of each roller 77 and an opening-surrounding portion of the bottom portion 73b, so that the interior of the chamber 73 is shielded from the space under the chamber 73.

The direction of movement of each roller 77 is limited by a guide rail 80 extending in the radial direction of the substrate W. In particular, as shown by the arrows in FIG. 19, each roller 77 moves toward the center C of the substrate W in the radial direction of the substrate W. An air cylinder 81 as a drive mechanism is coupled to each roller 77, so that the roller 77 is moved by the air cylinder 81 in the radial direction of the substrate W into contact with or away from the edge of the substrate W. The rollers are 77 disposed at regular intervals in the circumferential direction of the substrate W. The rollers 77 are each coupled to a motor (not shown) as a drive source, so that by driving the motors, the rollers 77 rotate in the same direction in synchronization.

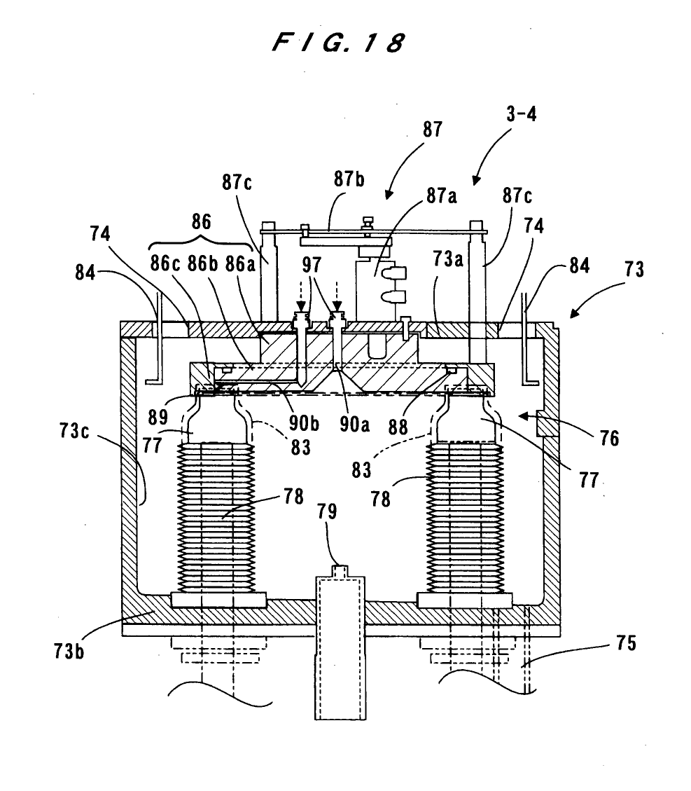

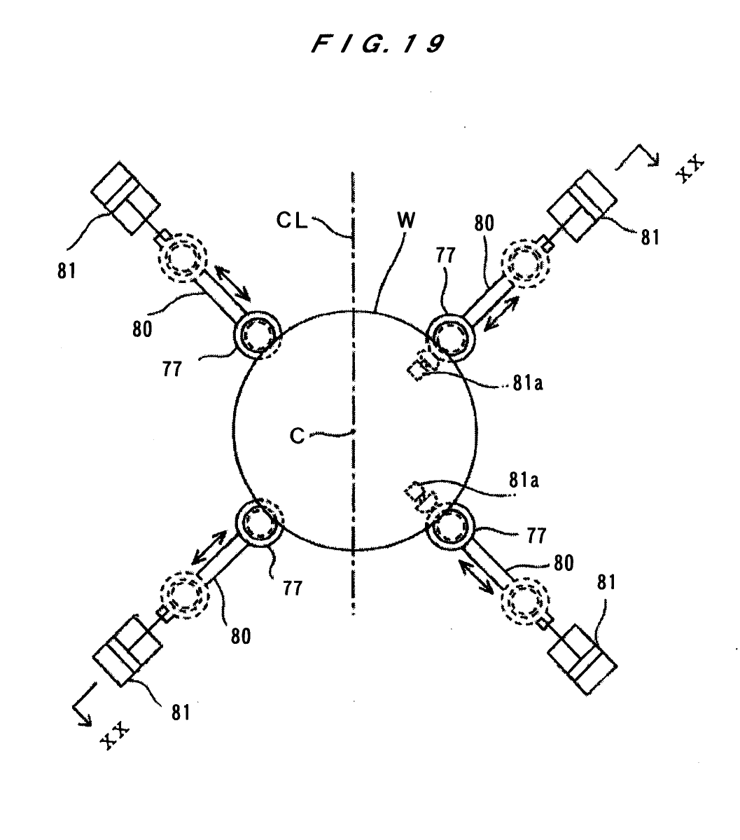

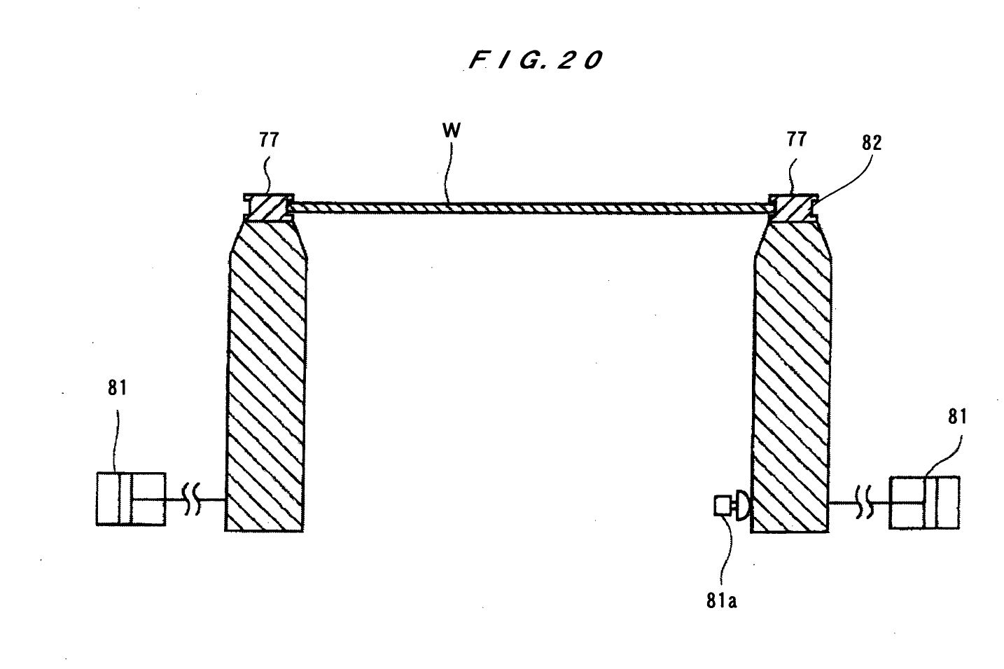

As shown in FIGS. 19 and 20, two stoppers 81a are provided for stopping the movements of those two rollers 77 which make contact with one of the two equally-divided areas, bisected by a center line CL, of the substrate W. Only one stopper 81a is shown in FIG. 20. The two rollers 77, each on receipt of a first pressure from the air cylinder 81, move toward the center C of the substrate W until they come into contact with the respective stoppers 81a, and are fixed at predetermined positions by the stoppers 81a. On the other hand, the other two rollers 77 located on the opposite side of the center line CL, each on receipt of a second pressure, which is lower than the first pressure, from the air cylinder 81, move toward the center C of the substrate W without limitation on the movement.

FIG. 21 is an enlarged cross-sectional view showing the main portion of the roller 77 shown in FIG. 20.

As shown in FIG. 21, each roller 77 has, near its top, a groove-shaped clamp portion 82 formed in the peripheral surface of the roller 77 and extending entirely around the roller 77. The clamp portion 82 centrally has a flat portion 82a, and has two curved portions 82b adjacent to the flat portion 82a above and below, having generally arc-shaped cross section as a whole. With this structure, when the roller 77 moves to the substrate W, the flat portion 82a comes into contact with the edge of the substrate W, when a peripheral portion of the substrate W, a portion extending inwardly from the edge to a distance of about 0.1 mm to several mm, is housed in the clamp portion 82. The rollers 77 have the same shape and the same size. A fluororesin having good chemical resistance, such as PVDF or PEEK, or polyurethane may preferably be used as a material for the rollers 77.

The width (length in the vertical direction) E of the clamp portion 82 is not more than twice a thickness T of the substrate W. Specifically, in the case of a substrate W having a diameter of 200 mm and a thickness of 0.75 mm, the width E of the clamp portion 82 is set at a value of not more than 1.5 mm. The width (length in the vertical direction) F of the flat portion 82a is not more than half of the thickness T of the substrate W. With such dimensions of the clamp portion 82, the position of the substrate W in the clamp portion 82 is restricted by the curved portions 82b such that it is fixed on the flat portion 82a. This makes it possible to rotate the substrate W while keeping the substrate W generally in a constant position.

The substrate holder 76 also includes a height adjustment mechanism (not shown) for adjusting the height of each roller 77 and a tilt adjustment mechanism (not shown) for adjusting the tilt of each roller 77. The height adjustment mechanism and the tilt adjustment mechanism make it possible to make the clamp portions 82 of all the rollers 77 parallel to each other and lie on the same horizontal plane.

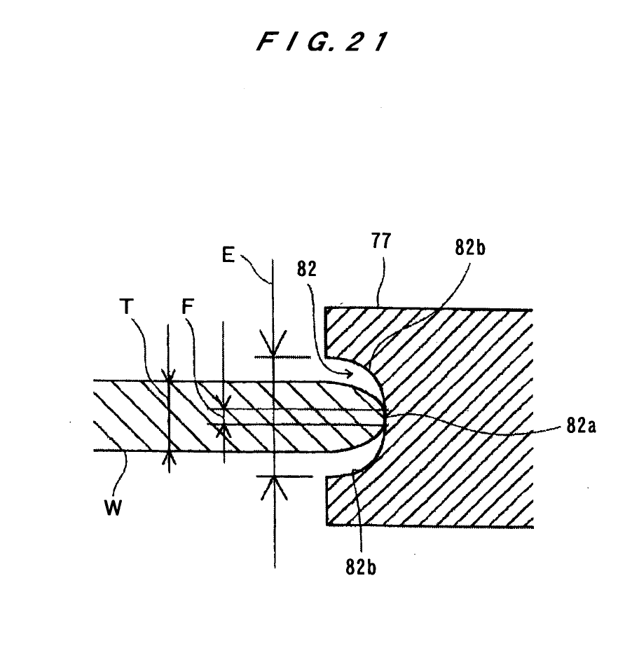

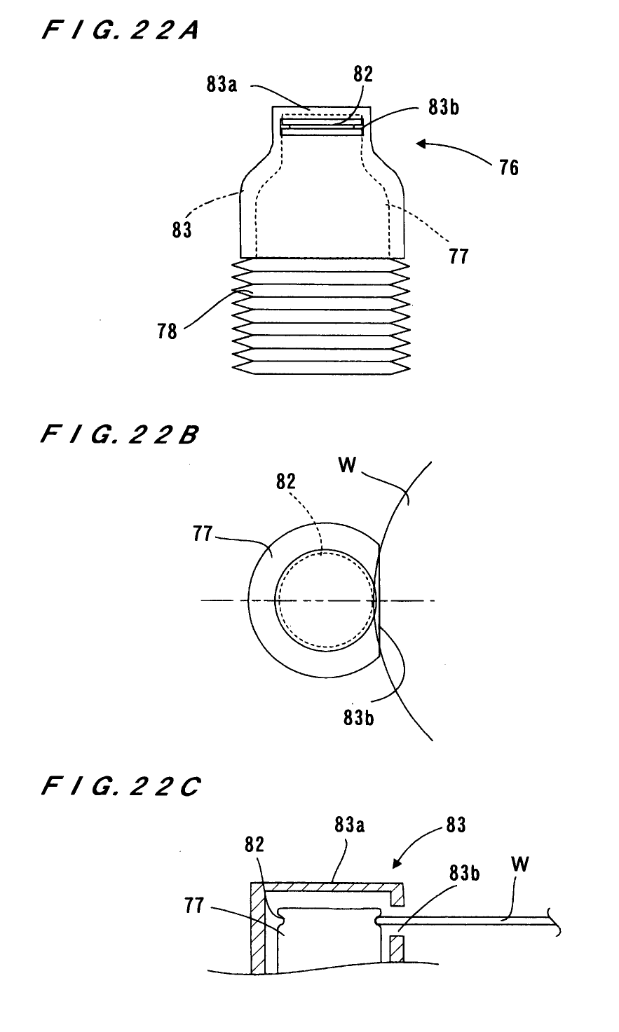

As shown in FIG. 22A, each roller 77 is provided with a roller cover 83 entirely covering the roller 77. The roller cover 83 has a cylindrical shape, conforming to the shape of the roller 77. The roller cover 83 is covered at its top with a top panel 83a, opens at its lower end in the chamber 73, and is mounted, directly or indirectly, to a base portion that holds a shaft of the roller 77. As shown in FIG. 22A, the roller cover 83 has, at a side portion near the top and opposite the clamp portion 82 of the roller 77, an opening 83b for inserting a peripheral portion of the substrate W. As shown in FIGS. 22B and 22C, the opening 83b is formed with such minimum vertical and horizontal dimensions that the roller cover 83 will not interfere with the substrate W held by rollers 77. Since the internal space of the roller cover 83 opens downward, a downward air flow is created in the space by discharge of air from the air discharge port 79, and liquid droplets or a liquid mist, which has intruded into the space from the opening 83b, is discharged downward by the downward airflow. The provision of the top panel 83a in the roller cover 83 prevents a processing liquid, etc., spattering from the substrate W, from adhering to the roller 77, thereby preventing the roller 77 from becoming a contamination source. It is also possible to discharge air from the internal space of the roller cover 83 through a flow path different from the flow path via the air discharge port 79 of the chamber 73.

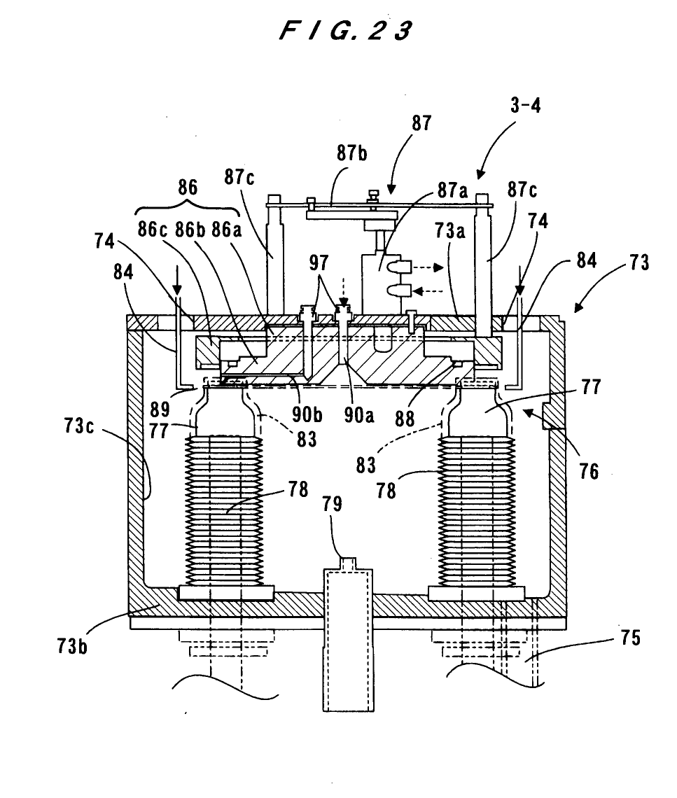

The chamber 73 is provided with processing liquid supply nozzles 84 for jetting various types of processing liquids toward the substrate W held by the rollers 77. The supply nozzles 84 are disposed such that they can jet an appropriate processing liquid for a particular type of processing to an appropriate portion of the substrate W, and are movable so that the jetting positions can be changed and that the supply nozzles 84 can retreat to a position apart from the substrate W when they are not in use. In this embodiment, the processing liquid supply nozzles 84 are provided to supply an etching liquid and cleaning pure water to the substrate W (semiconductor wafer) for bevel etching of the substrate W. Each supply nozzle 84 is comprised of a L-shaped pipe extending vertically downward from the top panel 83a. By swiveling the L-shaped pipe, the direction of the nozzle at the front end of the horizontal pipe can be changed, as will be appreciated from comparison between FIG. 18 and FIG. 23. The chamber 73 is also provided with a processing liquid supply nozzle 84 (not shown) for supplying cleaning pure water to the lower surface of the substrate W.

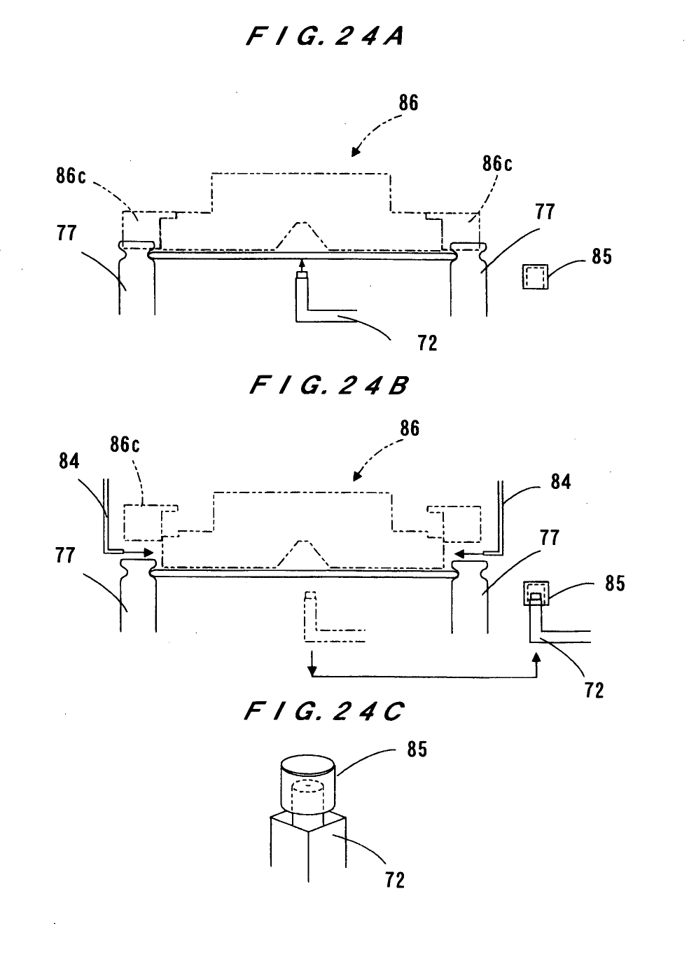

As shown in FIGS. 24A through 24C, the chamber 73 is also provided with gas jet nozzles 72 for jetting, e.g., an inert gas (N₂) toward appropriate portions of the substrate W to remove a processing liquid remaining on the substrate W or to prevent a processing liquid from adhering to unnecessary portions of the substrate W. The gas jet nozzles 72 also are each movable so as to jet a gas to a different portion of the surface of the substrate W and to retreat when not in use. Each gas jet nozzle 72 is provided with a nozzle cover 85 for preventing contamination or clogging of the nozzle 72 with spattered processing liquid when the nozzle is not in use. The nozzle cover 85 is cap-shaped and, in this embodiment, is disposed constantly in a nozzle retreat position. The gas jet nozzle 72 in the retreat position is raised by a lifting mechanism to insert the nozzle end into the cover. Instead of thus moving the nozzle 72, it is also possible to employ a manner in which the nozzle cover 85 is moved or raised/lowered, or a manner in which the nozzle cover 85 is moved together with the nozzle 72. The nozzle cover 85 is so oriented as to meet the jetting direction of the corresponding gas jet nozzle 72. Preferably, the gas jet nozzle 72 jets a small amount of gas even when it is moving in order to prevent adhesion of a processing liquid to the substrate surface. Though in this embodiment the nozzles cover is used for the gas jet nozzle 72 disposed below the substrate, the same nozzle cover may also be used for a gas nozzle 71 disposed above the substrate.

The chamber 73 is also provided with a purge member 86, mounted to the top panel 73a of the chamber 73, for controlling the flow of a processing liquid or a mist during processing of the substrate W. As shown in FIG. 18, the purge member 86 is comprised of a head portion 86a fixed to the top panel 73a, a disk-shaped fixed purge plate 86b fixed to a lower surface of the head portion 86a, and a movable purge plate 86c vertically-movably provided outside the fixed purge plate 86b. The movable purge plate 86c is mounted to the top panel 73a via a lifting mechanism 87. The lifting mechanism 87 includes a fluid pressure actuated cylinder 87a vertically mounted on the upper surface of the top panel 73a, a triangular holding plate 87b mounted to the upper end of the fluid pressure actuated cylinder 87a, and rod-like coupling members 87c coupling the edge portions of the holding plate 87b and the movable purge plate 86c. As shown in FIG. 23, the movable purge plate 86c moves upward by the actuation of the fluid pressure actuated cylinder 87a, whereby a peripheral area of the substrate W becomes exposed. When the movable plate 86c is in the lowered position, on the other hand, it is integrated with the fixed purge plate 86b. A seal member 88 is provided in that surface of the fixed purge plate 86b, which is to make contact with the movable purge plate 86c, so as to prevent a gas leak through a gap formed therebetween.

The movable purge plate 86c has at its periphery a protruding wall 89 having a diameter slightly larger than the diameter of the substrate W, so that the movable purge plate 86c can cover the upper surface and the side surface of the substrate W with small gaps therebetween. In order for the fixed purge plate 86b and the movable purge plate 86c not to interfere with other members such as the rollers 77, measures are taken in the purge plates 86b, 86c, such as the formation of recesses in relevant portions. The fixed purge plate 86b is provided with two gas flow passages 90a, 90b for supplying gasses toward the gap between the fixed plate 86b and the surface of the substrate W. The first gas flow passage 90a extends vertically along the central axis and has at the lower end an opening with expanding diameter, opening onto a central portion of the upper surface of the substrate W. The first gas flow passage 90a supplies a gas from the central portion toward the periphery of the substrate W. The second gas passages 90b opens onto a peripheral portion, a peripheral ring-shaped portion with a certain width from the edge, of the surface of the substrate W. The second gas flow passage 90b supplies a gas mainly to the peripheral portion of the substrate W. Fluids are supplied to the gas flow passages 90a, 90b via couplings projecting upward from the upper surface of the chamber 73.

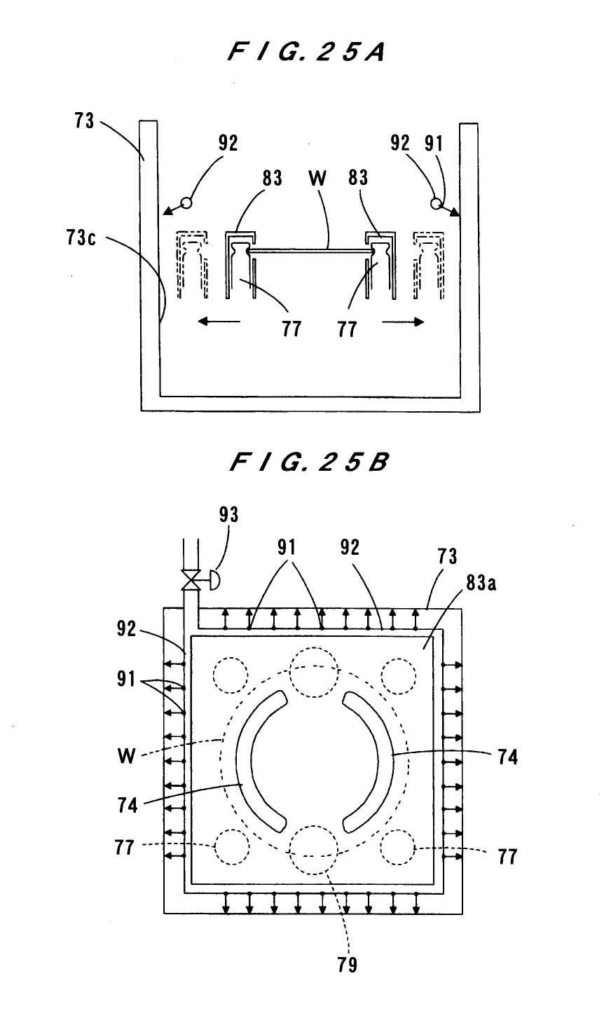

As shown in FIGS. 25A and 25B, the chamber 73 is provided with an inner wall cleaning nozzles 91 that open opposite to an inner wall 73c. In this embodiment, the inner wall cleaning nozzles 91 are oriented obliquely downward, and provided at regular internals in a pipe 92 which is provided along the inner wall 73c of the chamber 73. The pipe 92 is connected to a cleaning liquid supply system via an on-off valve 93 which is on-off controlled by a control system, so that automated cleaning (self-cleaning) of the inner wall 73c can be performed by opening the on-off valve 93 with predetermined timing.

The self-cleaning is usually carried out after processing one to several substrates and during standby time when the substrate W is, for example, being transported and thus is not in the chamber 73. It is, of course, possible to carry out self-cleaning even during processing, e.g., by using a low cleaning liquid jet pressure. Though the height position of the inner wall cleaning nozzles 91 may be selected arbitrarily, it is generally preferred to set the cleaning nozzles 91 at such a height position as to clean those areas of the inner wall 91 to which a processing liquid is likely to adhere, in particular, those areas at the same or lower height than the height of the substrate W on processing.

A description will now be given of a process of etching the peripheral bevel portion of the substrate W in the substrate processing unit 3-4 of the above construction. When the top panel 73a is open, the substrate W is carried into the chamber 73 by the transport robot 2. While keeping the substrate W at the height of the clamp portions 82, the rollers 77 are moved inwardly from the retreat positions to held substrate W. When the top cover 73a is closed, the substrate W is covered with the purge member 86, as shown in FIG. 18.

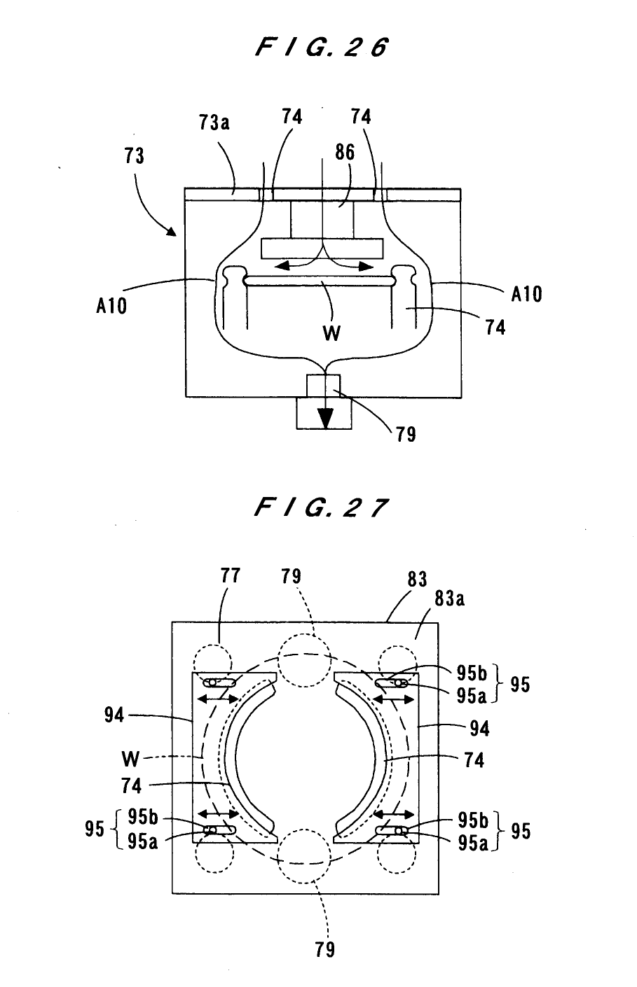

In this state, part of the air, which has passed through the fan filter unit 7, is guided into the space above the substrate processing unit 3-4, as shown in FIG. 7, and flows into the chamber 73 from the two arc-shaped air intakes 74 that open in the top panel 73a. As shown in FIG. 26, the air that has flowed in flows downward such that the airflow encircles the purge member 86 and the substrate W, and is discharged from the air discharge ports 79 provided at the bottom of the chamber 73.

Since the air intakes 74 are formed above the substrate W such that they extend along the periphery of the substrate W, such a downward airflow that encircles the substrate W is created in the chamber 73. Thus, air curtain A10, encircling the substrate W, is created, preventing contamination of the substrate W, e.g., with fine particles coming from the top panel 73a, the inner wall or other portions of the chamber 73. In this embodiment, a clean gas is supplied from the gas flow passages 90a, 90b of the purge member 86. This also protects the surface of the substrate W. In case the purge member 86 is not provided, the surface of the substrate W will be protected directly by the airflow.

Next, the movable purge plate 86c is raised to make the peripheral portion of the substrate W exposed, as shown in FIG. 23. A processing liquid is jetted from the processing liquid supply nozzles 84 toward the relevant portions while rotating the substrate W at a low speed by driving the rollers 77 in order to disperse the processing liquid uniformly. During the processing, an inert gas (e.g., N₂ gas) is supplied to the first gas flow passage 90a to create a gas flow flowing over the surface of the substrate W from the center toward the periphery. This prevents the processing liquid, jetted from the processing liquid supply nozzles 84, vapor from the liquid, etc. from intruding into the inner portion of the substrate W, thus protecting the inner portion. After completion of the etching processing, a cleaning liquid, such as pure water, is supplied from the processing liquid supply nozzles 84 to remove the etching liquid. Also during the cleaning, an inert gas (e.g., N₂ gas) is supplied to the first gas flow passage 90a, thereby preventing intrusion of a liquid into the inner portion of the substrate W. During the etching and the cleaning, a cleaning liquid is supplied also to the back surface of the substrate W to carry out cleaning of the back surface.

The process then proceeds to the step of removing the cleaning liquid from the substrate W and drying the substrate W. First, the supply of the cleaning liquid is stopped while the rotational speed of the substrate W is maintained or raised, thereby spattering the liquid by centrifugal force. An inert gas is supplied not only to the first gas flow passage 90a, but to the second gas flow passage 90b as well. Jetting of the gas from the first gas flow passage 90a is to prevent intrusion of the liquid into the inner portion of the substrate W, while jetting of the gas from the second gas flow passage 90b is to blow off the liquid remaining on the peripheral portion of the substrate W. When the amount of the liquid remaining on the substrate W has substantially decreased, the movable purge plate 86c is lowered to cover the peripheral portion of the substrate W with it. This can create a high-speed flow of the inert gas along the surface of the peripheral portion of the substrate W, enabling quick removal of the liquid, i.e., drying. In the drying step, the substrate W is either rotated at a lowered rotational speed or the rotation is stopped.

In the cleaning liquid removal/drying step, a gas is supplied also to the back surface of the substrate W from the gas supply nozzle 72, thereby carrying out removal of the liquid and drying, as shown in FIG. 24A. After completion of the drying, the gas jet nozzle 72 moves to the retreat position while jetting a small amount of gas, as shown in FIG. 24B, and moves upward in the retreat position so that the front end is housed in the nozzle cover 85, as shown in FIG. 24C.

The substrate W after completion of the processing is carried by the transport robot out of the chamber 73 whose top panel 73a is open, and a new substrate W is carried into the chamber 73 for the next processing. During the interval between processings, automated cleaning (self-cleaning) of the inner wall 73c is carried out with appropriate timing by the inner wall cleaning nozzles 91 shown in FIGS. 25A and 25B.

In the above-described process, the etching, the cleaning and the liquid removal/drying steps are carried out in the same unit. Accordingly, a substrate W during or after the liquid removal/drying step can be contaminated with contaminants coming from various portions of the unit which have been contaminated in the etching or cleaning step. Prevention of such secondary contamination is therefore an important problem. In order to prevent secondary contamination, the substrate processing unit of this embodiment is provided with the above-described various means:

Firstly, the provision of the air intakes 74, disposed symmetrically with respect to a substrate W, creates an air curtain that uniformly encircles the substrate W. The air curtain can prevent or reduce spattering of a processing liquid from the substrate W being processed with the liquid or from a nozzle on various surrounding members or on the inner wall, thus preventing or reducing contamination of these portions of the unit. Furthermore, the air curtain prevents contaminate of the substrate W via the surrounding members or the inner wall in the liquid removal/drying step. Secondary contamination of the substrate W can thus be further prevented or reduced.

It will be convenient if the opening area or the shape of the air intake 74 can be changed depending on the situation. Though replacement of the top panel 73a or the air intake 74 is possible, it will involve a considerable labor. FIG. 27 illustrates an embodiment which enables an easy change of the opening area or the shape of the air intake 74. Two adjustment members 94, each having an edge portion of a shape conforming to the shape of each air intake 74, are mounted to the upper surface of the top panel 73a such that they each partly cover the air intake 74. Position adjustment mechanisms 95, each comprised of a combination of a protrusion 95a and a long aperture 95b, are provided between the top panel 73a and each adjustment member 94. The positions of the two adjustment members 94 can be adjusted while maintaining their symmetry with respect to the substrate by using the position adjustment mechanisms 95. It is possible to thread each protrusion 95a and fix the adjustment member 94 by screw-engaging a nut with the threaded protrusion 95a. It is also possible to change the shape of the air intake 74 by using an adjustment member 94 having a different shape of edge portion.

Secondary, the use of the roller cover 83, which covers the roller 77 which is to make direct contact with a substrate W, can reduce adhesion of a processing liquid to the roller 77, thus preventing or reducing secondary contamination of the substrate W via the roller 77. Covering of the top of the roller 77 with the top panel 83a is especially effective.

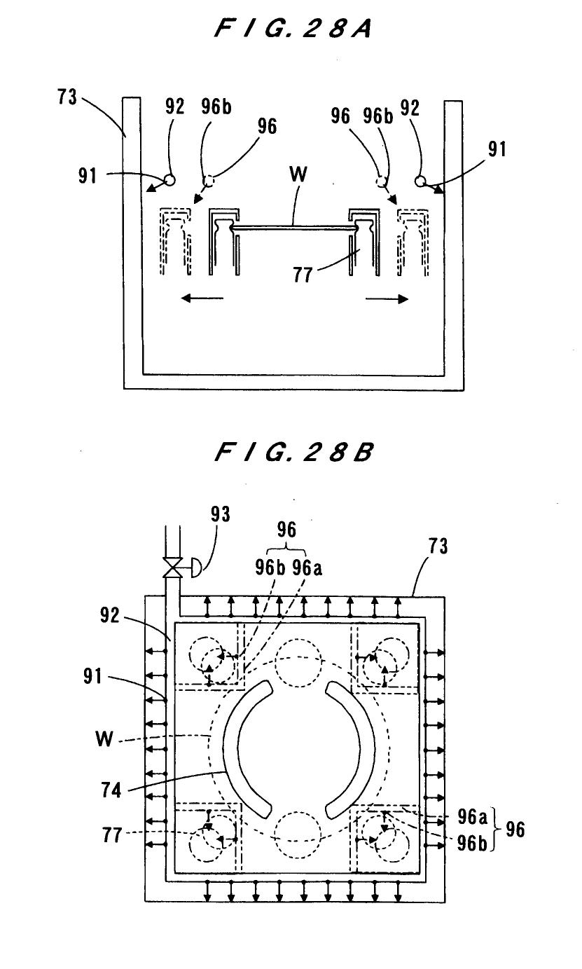

Though the roller cover 83 itself does not make contact with a substrate W, it can be a contamination source if a processing liquid, etc. adheres to it excessively. FIGS. 28A and 28B show a cover cleaning mechanism 96 for cleaning the roller cover 83 in the retreat position of the roller 77. In this embodiment, a pipe 96a is introduced above the opening 83b of each roller cover 83 from the pipe 92 for the inner wall cleaning nozzles 91, shown in FIGS. 25A and 25B, and a cover cleaning nozzle 96b is formed in the pipe 96a. The timing of cleaning of the roller cover 83 may be basically the same as self-cleaning of the inner wall 73c, though not limited thereto. A cover cleaning mechanism is not limited to the above-described mechanism 96. For example, it is possible to provide the roller cover 83 with a nozzle for jetting a cleaning liquid from the inside of the opening 83b.

Thirdly, the nozzle cover 85 prevents or reduces contamination of the gas jet nozzle 72 in the retreat position, thus avoiding jetting of a gas from a contaminated gas jet nozzle 72. This also prevents or reduces secondary contamination of a substrate W.

Fourthly, self-cleaning of the inner wall 73c is carried out by the inner wall cleaning nozzles 91. This prevents or reduces secondary contamination of a substrate W through a contamination route in which fine particles, coming from a processing liquid, etc. attached to the inner wall 73c, adhere to the substrate W.

Besides the above four means, it is possible to additionally employs the below-described holder suction section, provided in a substrate holder, for sucking in a processing liquid. This can prevent the processing liquid from adhering to the substrate holder, thus preventing or reducing adhesion of fine particles, coming from the processing liquid attached to the substrate holder, to a substrate W.

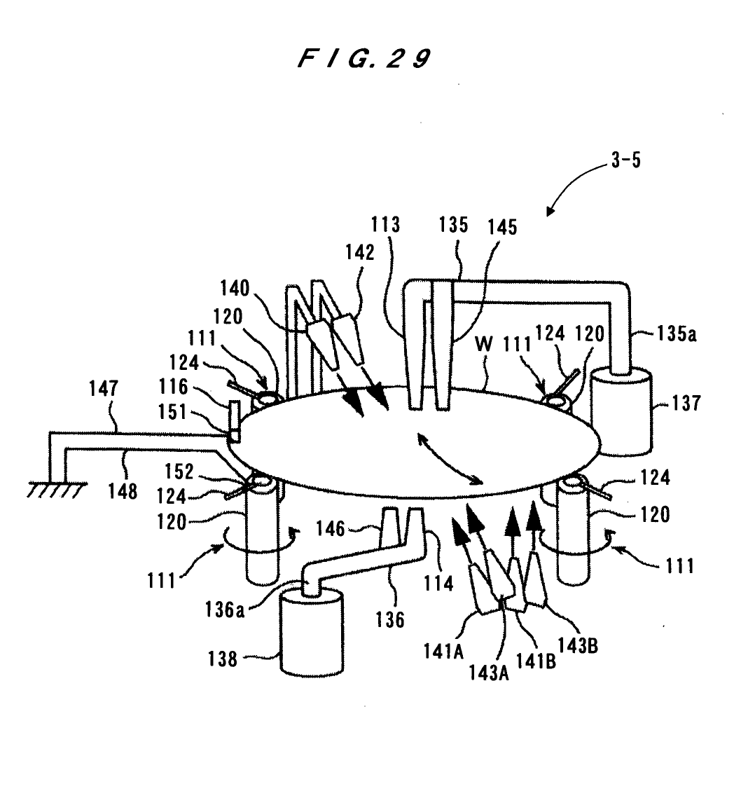

FIG. 29 is a perspective view schematically showing a substrate processing unit 3-5 according to another embodiment of the present invention. As shown in FIG. 29, the substrate processing unit 3-5 includes a plurality of substrate holders 111 (4 holders in this embodiment) each comprising a roller 120 that rotates about its axis. A bevel suction nozzle (peripheral suction section) 116 is disposed above a substrate W. The bevel suction nozzle 116 is disposed in the vicinity of a peripheral portion of the substrate W, and sucks in a liquid from the peripheral portion of the substrate W.

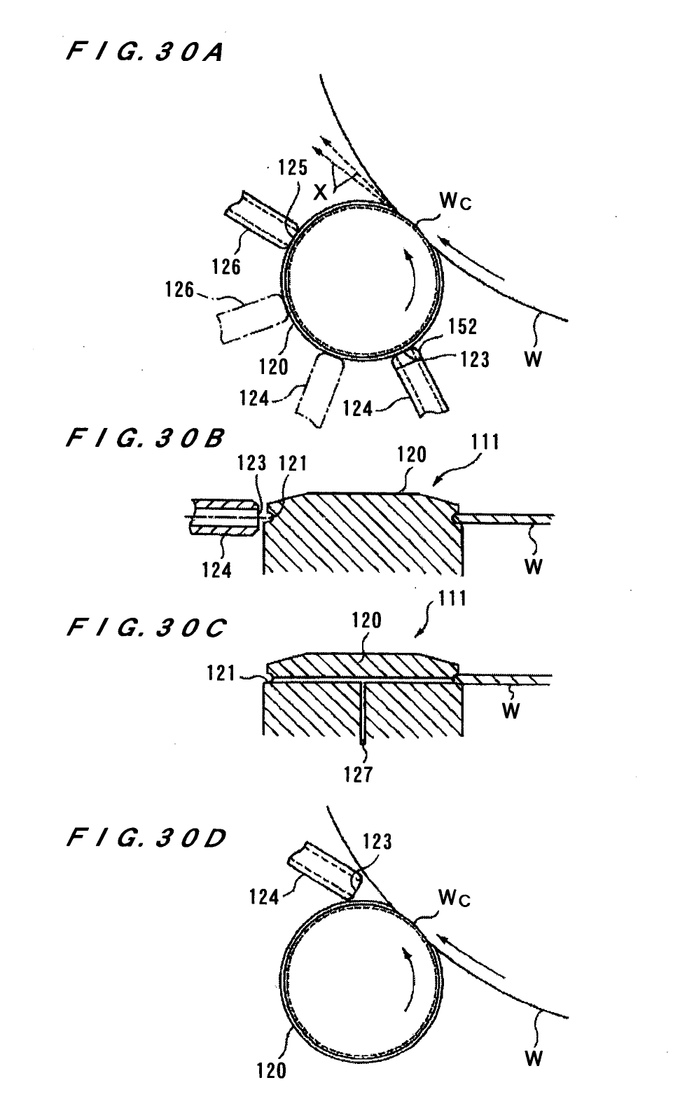

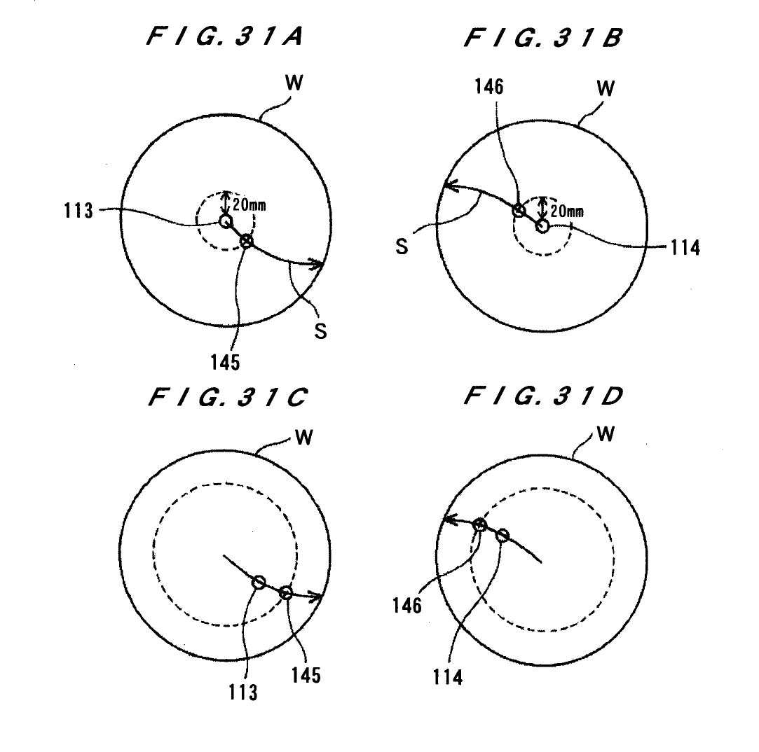

FIGS. 30A and 30B are diagrams illustrating an embodiment of the substrate holder 111. The substrate holders (rotary holders) 111 for holding a substrate each comprise a roller 120 having a clamp portion 121. The clamp portion 121 makes contact with an edge of the substrate W with a predetermined pressure applied on the substrate W in a direction toward approximately the center of the substrate W. By rotating all the substrate holders 111 at a predetermined rotational speed in the same direction by not-shown rotating means, the substrate holders 111 hold the substrate W while imparting a rotating power to the substrate W by friction between the substrate holders 111 and the peripheral edges of the substrate W. It is also possible to rotationally drive at least one of all the substrate holders 111. A holder suction nozzle 124, having a suction port 123 for sucking in a fluid, such as a processing liquid, is disposed in the vicinity of the clamp portion 121 of each roller 120. The suction port 123 is disposed at a short distance, e.g., not more than 5 mm, from the clamp portion 121, and sucks in a fluid adhering to the clamp portion 121. Further, a holder cleaning nozzle 126, having a supply port 125 for supplying a cleaning fluid to the clamp portion 121, is also disposed in the vicinity of the clamp portion 121 of each roller 120. In this embodiment, PVDF, which is a chemical-resistant fluororesin, is used as a material for the roller 120.

In case a substrate is held by using spin chucks which fix the substrate by claws, a fluid is likely to stay inside the claws with little replacement of the fluid. In contrast thereto, by rotatably holding a substrate W by the substrate holders 111 and providing each substrate holder 111 with the holder suction section 124, it becomes possible to prevent a fluid from staying in the vicinity of the substrate holders 111, thus enhancing replacement of the fluid. The clamp portions 121 of the substrate holders 111 make contact with the edge of the substrate W, and hold the substrate W by pressing on the substrate W inwardly at a predetermined pressure. The clamp portion 121 preferably is concaved to avoid a displacement of the substrate W during holding or rotation of the substrate W. Further, the clamp portion 121 preferably has the shape of a perfect circle, as viewed from right above. The clearance between the holder suction nozzle 124 and the clamp portion 121 is desirably not more than 1 mm, more desirably not more than 0.5 mm. A fluororesin having good chemical resistance, such as PVDF, PEEK, or the like, or polyurethane may preferably be used as a material for the roller 120. As with the clearance between the holder suction nozzle 124 and the clamp portion 121, the clearance (positional relationship) between the holder cleaning nozzle 126 and the clamp portion 121 is desirably not more than 1 mm, more desirably not more than 0.5 mm.

Without the holder suction nozzle 124, a fluid that has adhered to the clamp portion 121 again comes into contact with the substrate W by the rotation of the roller 120, and the fluid spatters in the tangential direction X at the point of contact between the substrate W and the roller 120 (see FIG. 30A). In order to prevent such spattering of liquid, the suction port 123 and the supply port 125 are disposed in the following manner: If the roller 120 rotates in the direction of the arrow shown in FIG. 30A, the holder cleaning nozzle 124 is disposed ahead of the contact point Wc between the clamp portion 121 and the substrate W in the rotating direction, and the holder suction nozzle 124 having the suction port 123 is disposed ahead of the substrate cleaning nozzle 126. Thus, a fluid on the peripheral portion of the substrate W moves at the contact point Wc to the clamp portion 121 of the roller 120, and the clamp portion 121 with the fluid on it moves in the rotating direction of the roller 120 and is cleaned by a cleaning liquid supplied from the cleaning fluid supply port 125 of the holder cleaning nozzle 126. The fluid, processed by the cleaning fluid, moves by the rotation of the roller 120 and reaches a position in front of the holder suction nozzle 124 having the suction port 123, where the fluid is sucked into the suction nozzle 124. Spattering of the fluid from the periphery of the substrate W can thus be prevented, thereby preventing contamination and the formation of watermarks on the substrate. Further, a fluid adhering to the peripheral portion of the substrate can be sucked in by the bevel suction nozzle 116. A fluid adhering to the peripheral portion of the substrate can thus be effectively removed with ease even when the substrate is rotated at a low speed.

As shown in the cross-sectional diagram of FIG. 30C, it is also possible to provide a suction pipe 127 in the interior of the roller 120 so that a fluid is sucked from one or more portions of the clamp portion 121 into the suction pipe 127. Though this embodiment employs the holder cleaning nozzle 126, it can be omitted the holder cleaning nozzle 126 in the case where cleaning processing is not necessary. The suction port 123 of the holder suction nozzle 124 and the suction pipe 127 communicates with a vacuum source via a gas-liquid separator and sucks in a fluid, etc. by vacuum suction. An ejector, a vacuum pump, etc. may be used as the vacuum source.

The holder cleaning nozzle 126 and the holder suction nozzle 124 may be disposed at a distance from the substrate W, as indicated by the dashed-dotted lines in FIG. 30A, so that a fluid on the substrate W will not adhere to the holder cleaning nozzle 126 and the holder suction nozzle 124. Thus, the holder cleaning nozzle 126 and the holder suction nozzle 124 may be disposed on the opposite side of the center of the roller 120 from the contact point Wc.

In the case of sucking in a fluid on the substrate W by the bevel suction nozzle 116 or a not-shown suction nozzle, the roller 120 need not necessarily be cleaned. Thus, the holder cleaning nozzle 126 can be omitted. In this case, as shown in FIG. 30D, the holder suction nozzle 124 is preferably disposed on the tangent to the roller 120 and the substrate W, and ahead of the contact point Wc in the rotating direction of the roller 120. Further, in this case, the suction port 123 of the holder suction nozzle 124 preferably opens toward the contact portion Wc, and is disposed in the vicinity of the contact portion Wc. The holder suction nozzle 124 may be disposed such that the suction port 123 is kept in contact with a fluid remaining on the contact point Wc.

In this embodiment, the bevel suction nozzle 116 has a conductive portion 151 formed of a conductive material. The conductive portion 151 is positioned at the front end of the bevel suction nozzle 116, and is grounded via a conducting wire 147. Though, in this embodiment, only part of the bevel suction nozzle 116 is formed of a conductive material, the bevel suction nozzle 116 may also be entirely formed of a conductive material. Further, it is also possible to provide a bevel suction nozzle on the lower surface side of the substrate W.

The holder suction nozzle 124 has a conductive portion 152 formed of a conductive material. The conductive portion 152 is positioned at the front end of the holder suction nozzle 124, and is grounded via a conducting wire 148. Though, in this embodiment, only part of the holder suction nozzle 124 is formed of a conductive material, the holder suction nozzle 124 may also be entirely formed of a conductive material. It suffices if at least one of the four holder suction nozzles 124 has the conductive portion 152.

A gas supply nozzle 113, for supplying a drying gas to an upper surface of the substrate W, is disposed above the substrate W, while a gas supply nozzle 114, for supplying a drying gas to a lower surface of the substrate W, is disposed below the substrate W. The gas supply nozzles 113, 114 extend substantially vertically with respect to the substrate W, and drying gasses can be jetted from the gas supply nozzles 113, 114 toward the upper surface and the lower surface of the substrate W, respectively. The gas supply nozzle 113 is mounted to the front end of a pivot arm 135, and a pivot shaft 135a of the pivot arm 135 is coupled to a drive source (movement mechanism) 137. Upon actuation of the drive source 137, the pivot arm 135 pivots and the gas supply nozzle 113 moves along the radial direction of the substrate W. As with the gas supply nozzle 113, the gas supply nozzle 114 is also mounted to the front end of a pivot arm 136, and is coupled via a pivot shaft 136a to a drive source 138. By actuation of the drive source 138, the gas supply nozzle 114 moves along the radial direction of the substrate W.

An inert gas, such as N₂ gas, is preferably used as the drying gas. The pressure of the drying gas supplied from the gas supply nozzles 113, 114 is preferably 50 kPa to 350 kPa. If the gas pressure is too low, poor drying may occur even when the gas supply nozzles 113, 114 are moved at a low speed. If the gas pressure is too high, on the other hand, a liquid film on the substrate W can spatter as liquid droplets when the gas is jetted onto the liquid film, and the liquid droplets may adhere to the substrate W, causing watermarks. For these reasons, it is preferred to supply the gas at a pressure of 50 kPa to 350 kPa from the gas supply nozzles 113, 114.

To the pivot arms 135, 136 are mounted liquid supply nozzles 145, 146, respectively, for supplying a predetermined liquid, such as pure water, to the substrate W. As with the gas supply nozzles 113, 114, the liquid supply nozzles 145, 146 extend substantially vertically with respect to the substrate W. The predetermined liquid can be supplied to the upper surface of the substrate W from the liquid supply nozzle 145 located above the substrate W, whereas the predetermined liquid can be supplied to the lower surface of the substrate W from the liquid supply nozzle 146 located below the substrate W. The liquid supply nozzle 145, 146 are disposed adjacent to the gas supply nozzles 113, 114, and move, together with the gas supply nozzles 113, 114, respectively, in the radial direction of the substrate W.

The positional relationship between the gas supply nozzles 113, 114 and the liquid supply nozzles 145, 146 will now be described with reference to FIGS. 31A through 31D. FIGS. 31A through 31D are diagrams illustrating the positional relationship between the gas supply nozzles and the liquid supply nozzles shown in FIG. 29.

As shown in FIGS. 31A and 31C, the liquid supply nozzle 145 is disposed radially outside the gas supply nozzle 113, i.e., located at an outer position than the gas supply nozzle 113 in the radial direction of the substrate W. The liquid supply nozzle 145 and the gas supply nozzle 113, both secured to the pivot arm 135 (see FIG. 29), move in an arc track as shown by the arrow S along the radial direction of the substrate W while maintaining their relative position. Thus, when the liquid supply nozzle 145 and the gas supply nozzle 113 move toward the periphery of the substrate W, the liquid supply nozzle 145 lies ahead of the gas supply nozzle 113 in the moving direction. The distance between the liquid supply nozzle 145 and the gas supply nozzle 113 in the radial direction of the substrate W is preferably in the range of 10 to 30 mm, and is 20 mm in this embodiment. If the distance between the liquid supply nozzle 145 and the gas supply nozzle 113 is too short, there is a fear of spattering of the liquid, supplied from the liquid supply nozzle 145, by the gas from the gas supply nozzle 113. If the distance between the liquid supply nozzle 145 and the gas supply nozzle 113 is too long, on the other hand, there will be those portions of the surface of the substrate W which are not protected by the liquid. The distance between the liquid supply nozzle 145 and the gas supply nozzle 113 is thus preferably made in the range of 10 mm to 30 mm.

The positional relationship between the liquid supply nozzle 146 and the gas supply nozzle 114 is the same as the above-described positional relationship between the liquid supply nozzle 145 and the gas supply nozzle 113. Thus, as shown in FIGS. 31B and 31D, the liquid supply nozzle 146 is located at an outer position than the gas supply nozzle 114 in the radial direction of the substrate W. The distance between the liquid supply nozzle 146 and the gas supply nozzle 114 is preferably in the range of 10 to 30 mm, and is 20 mm in this embodiment. It is also possible to provide two or more gas supply nozzles above and below the substrate W, respectively. Similarly, it is also possible to provide two or more liquid supply nozzles above and below the substrate W, respectively.

It is also possible to mount one more liquid supply nozzles and one or more gas supply nozzles to one or more pivot arms different from the pivot arm 135, as the liquid supply nozzle 145 and the gas supply nozzle 113 mounted to the pivot arm 135, and allow the nozzles to move in different arc tracks from the center toward the periphery of the substrate W in carrying out drying of the substrate surface. The substrate W can be dried uniformly by allowing the nozzles to move in such arc tracks that extend approximately radially at an equal angle from the center to the periphery of the substrate W. The above may apply equally with liquid supply nozzles and gas supply nozzles to be used for the back surface of the substrate W. Further, instead of moving the liquid supply nozzles and the gas supply nozzles in an arc track or arc tracks, it is also possible to move the nozzles linearly from the center to the periphery of the substrate W.

An example of the operation of the substrate processing unit 3-5 having the above construction will now be described. The following description illustrates the case of using as a substrate W a semiconductor wafer having a Cu film and a film of low-k material formed in the upper surface and an oxide film formed in the lower surface, and supplying a liquid to the substrate W only from the liquid supply nozzle 145 disposed above the substrate W.

First, the substrate W is held by the rollers 120 of the substrate holders 111, and is rotated at a rotational speed of 35 mm⁻¹. While rotating the substrate W, a rinsing liquid (pure water) as a processing liquid is supplied from a rinsing liquid supply nozzle 140 to the upper surface of the substrate W, and a rinsing liquid (pure water) as a processing liquid is supplied from rinsing liquid supply nozzles 141A, 141B to the lower surface of the substrate W, thereby forming a liquid film of pure water on the upper and lower surfaces of the substrate W.

Next, the gas supply nozzles 113, 114 and the liquid supply nozzles 145, 146 are moved toward the center of the substrate W. Simultaneously with or immediately before stopping the supply of pure water from the rinsing liquid supply nozzles 140, 141A, 141B, N₂ gas at a pressure of 300 kPa begins to be supplied from the gas supply nozzles 113, 114 to the upper and lower surfaces of the substrate W while pure water begins to be supplied at a flow rate of 400 cc/min from the liquid supply nozzle 145 to the upper surface of the substrate W. In this state, the rotational speed of the substrate W is increased to 80 min⁻¹, and the gas supply nozzles 113, 114 and the liquid supply nozzles 145, 146 are moved toward the periphery of the substrate W, thereby drying the upper and lower surfaces of the substrate W.

By supplying pure water from the liquid supply nozzle 145 to the upper surface of the substrate W while moving the liquid supply nozzle 145, a liquid film is formed on the upper surface of the substrate W, thereby protecting the upper surface of the substrate W. The N₂ gas supplied from the gas supply nozzle 113, while forcing the liquid film to move to the periphery of the substrate W, dries the upper surface of the substrate W. The liquid film (pure water), which has moved to the periphery of the substrate W, is sucked into the bevel suction nozzle 116. Further, the pure water, which has moved from the substrate W to the roller 120, is sucked into the holder suction nozzle 124. Since the liquid film is thus removed almost simultaneously with the formation of the liquid film, the substrate W can be dried without the formation of watermarks on the upper surface of the substrate W.

Upon suction of pure water on the substrate W by the bevel suction nozzle 116 and the holder suction nozzles 124, pure water and air are mixed to cause friction and the friction generates static electricity. In this embodiment, the bevel suction nozzle 116 and the holder suction nozzle 124 are grounded via the conductive portions 151, 152, respectively, preventing electrostatic charging of the substrate W. This can avoid an adverse effect of static electricity on a circuit formed in the upper surface of the substrate W, thereby increasing the yield. It is also possible to form at least part of the substrate holder 111 (roller 120) of a conductive material, and ground the conductive portion. This also enables removal of static electricity.

Though the supply of a liquid only from the liquid supply nozzle 145, disposed above the upper surface of the substrate W, has been described above, a liquid may also be supplied to the lower surface of the substrate W from the liquid supply nozzle 146 disposed below the lower surface of the substrate W, depending on the type of a film formed on the lower surface of the substrate W. In the case where the upper surface and the lower surface of the substrate W have different wetting properties, it is preferred to adjust the time for drying the substrate W according to the different wetting properties. For example, when the hydrophobicity of the upper surface of the substrate W is higher than the lower surface, movement of the gas supply nozzle 113 and the liquid supply nozzle 145, disposed above the upper surface of the substrate W, is started after starting movement of the gas supply nozzle 114 and the liquid supply nozzle 146, disposed below the lower surface of the substrate W. In this case, in order to simultaneously complete drying of the upper surface and drying of the lower surface, the upper nozzles and the lower nozzles are moved at different speeds so that the upper gas supply nozzle 113 and the lower gas supply nozzle 114 will reach the periphery of the substrate W simultaneously. Drying of the upper and lower surfaces, having different wetting properties, can thus be completed simultaneously. This can effectively prevent the formation of watermarks.

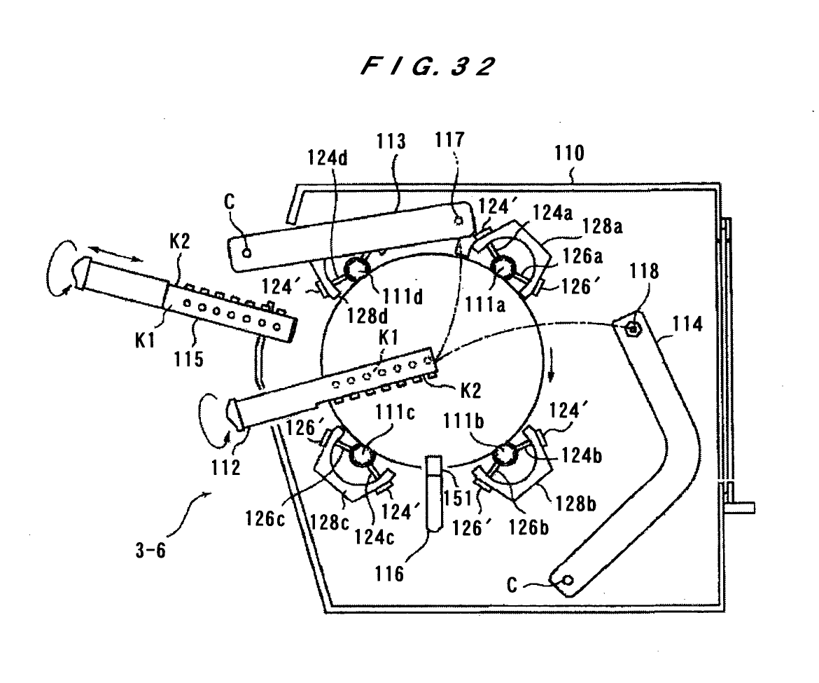

A substrate processing unit 3-6 according to another embodiment of the present invention will now be described. FIG. 32 is a schematic plan view showing an embodiment of the substrate processing unit 3-6. The substrate processing unit 3-6 includes a chamber 110 in which a substrate W to be processed, such as a semiconductor wafer, is rotatably held by substrate holders 111 (111a, 111b, 111c, 111d). The substrate holders 111 (111a, 111b, 111c, 111d) are respectively provided with holder suction nozzles (holder suction sections) 124 (124a, 124b, 124c, 124d) and holder cleaning nozzles (holder cleaning sections) 126 (126a, 126b, 126c, 126d), each section nozzle 124 and each cleaning nozzle 126 both being disposed in the vicinity of each substrate holder 111. The holder suction nozzles 124a, 124b, 124c, 124d and the holder cleaning nozzles 128a, 128b, 128c, 128d are supported by support sections 128a, 128b, 128c, 128d, respectively. The clearance between each holder suction nozzle 124 and each substrate holder 111 can be adjusted by an adjustment section 124′, and the clearance between each holder cleaning section 126 and each substrate holder 111 can be adjusted by an adjustment section 126′. Cleaning nozzles (substrate processing sections) 112, 115, each having a fluid supply port and a fluid suction port, are provided above and below the substrate W. The cleaning nozzles 112, 115 are movable in the radial direction of the substrate W, as shown by the dashed-two dotted line (dashed-two dotted line omitted for the cleaning nozzle 115) in the Figure.

Gas supply nozzles 113, 114 for supplying an inert gas, such as N₂ gas, or a drying gas, such as dry air having humidity of not more than 10%, are provided above and below the substrate W. The gas supply nozzles 113, 114 have gas supply ports 117, 118, respectively. The gas supply nozzles 113, 114 are each pivotable about a supporting point C approximately along the radial direction of the substrate W as shown by the dashed-dotted line in the Figure. The substrate processing unit 3-6 also includes a bevel suction nozzle (peripheral suction section) 116 for sucking in a fluid on the peripheral portion of the substrate W. Though four substrate holders 111 are shown in the Figure, the number of the substrate holders 111 is not particularly limited insofar as it is not less than 3. A fluid, such as a cleaning fluid, an etching liquid, an etching gas, etc. may be supplied from the cleaning nozzles. Specific examples include a corrosive gas such as hydrogen fluoride, an acid such as hydrofluoric acid, an oxidizing agent such as hydrogen peroxide, nitric acid or ozone, an alkaline chemical such as ammonia, a chelating agent, a surfactant, and a mixture thereof.

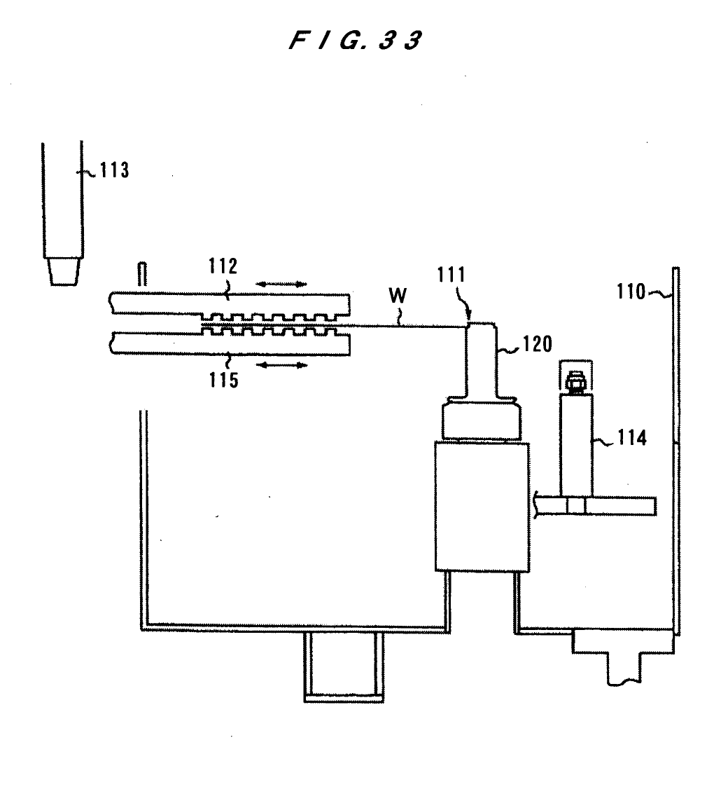

FIG. 33 illustrates the state of the substrate processing unit shown in FIG. 32 upon cleaning of the front and back surfaces of the substrate W. As shown in FIG. 33, the upper cleaning nozzle (substrate processing section) 112 is moved by a lifting means (not shown) to a position at a predetermined height and close to the front surface of the substrate W, while the lower cleaning nozzle (substrate processing section) 115 is moved by a lifting means (not shown) to a position at a predetermined height and close to the back surface of the substrate W. Also in this unit, the substrate W is held horizontally by the substrate holders 111, comprised of the rollers 120, with a rotating power being imparted to the substrate W. The upper gas supply nozzle 113 and the lower gas supply nozzle 114 are in their respective retreat positions. After the completion of cleaning, the upper cleaning nozzle 112 retreats to a retreat position lying in the radial direction of the substrate W, while the upper gas supply nozzle 113 in turn moves to a predetermined position over the upper surface of the substrate W and supplies a drying gas to the upper surface to carry out drying of the upper surface. Similarly, the lower cleaning nozzle 115 retreats to a lower retreat position lying in the radial direction of the substrate W, while the lower gas supply nozzle 114 in turn moves to a predetermined position and supplies a gas to the lower surface of the substrate W to carry out dying of the lower surface.

The cleaning nozzles 112, 115 each has a plurality of fluid supply ports and a plurality of fluid suction ports, for example about 10 supply ports and about 10 suction ports when processing a substrate having a diameter of 200 mm, arranged alternately and spaced apart from each other so that a fluid (liquid), such as a cleaning liquid, is supplied from the fluid supply ports to the substrate W while the fluid (liquid) adhering to the substrate W is sucked into the fluid suction ports. Processing, such as cleaning, is carried out by supplying and sucking in a fluid (liquid) by the fluid supply ports and the fluid suction ports while reciprocating the supply ports and the suction ports. This manner of processing has the advantages that spattering of the fluid (liquid) from the substrate surface can be prevented and the amount of the fluid (liquid) remaining on the substrate after processing can be decreased to a very small amount.

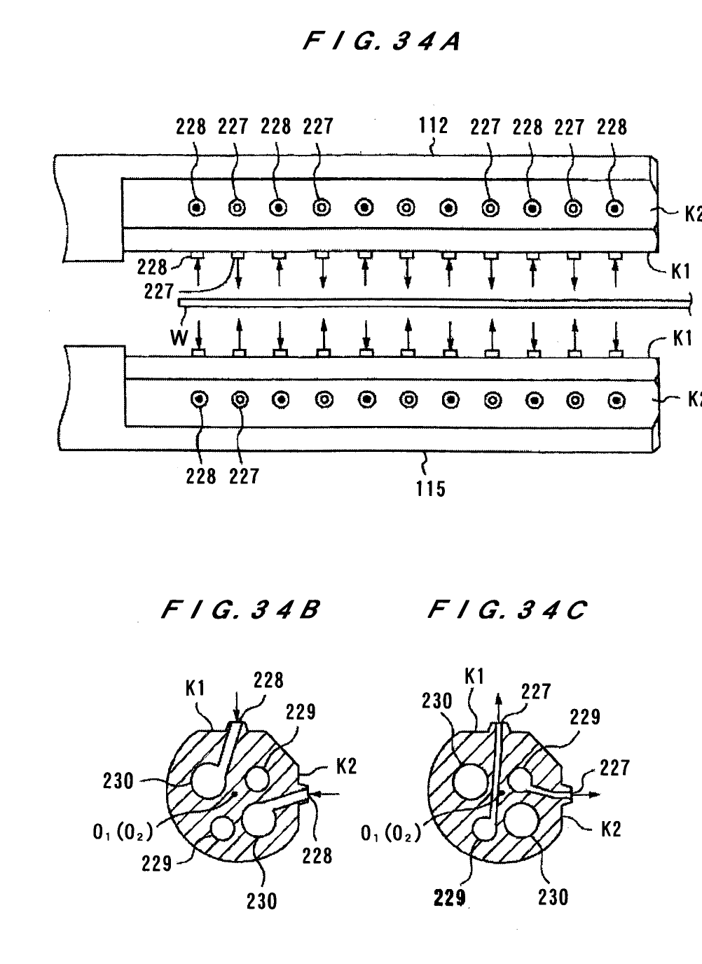

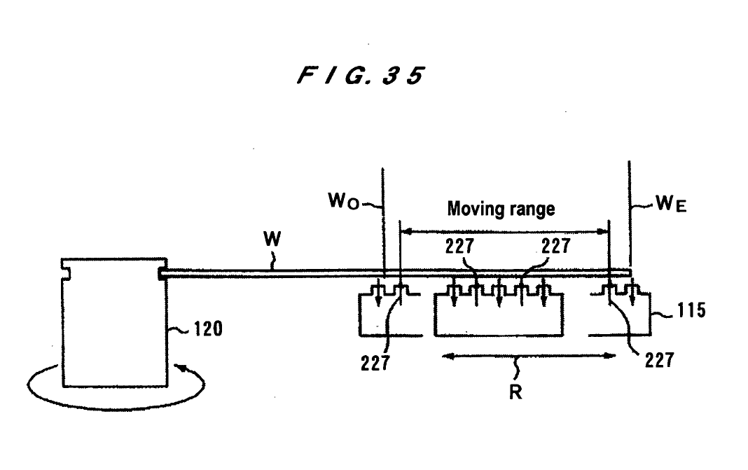

FIGS. 34A through 34C illustrate an embodiment of the cleaning section. The cleaning nozzles 112, 115 each have working faces K1, K2 in the nozzle body. In each working face, supply ports 227 and suction ports 228 for a fluid (liquid) are arranged alternately in line. As shown in FIGS. 34B and 34C, the supply ports 227 of each working face are connected to a common supply pipe 229, while the suction ports 228 are connected to a common liquid/gas discharge pipe 230. Thus, when a fluid (liquid) is supplied to the supply pipe 229, the fluid (liquid) is supplied through the supply ports 227 to a substrate surface. On the other hand, the fluid (liquid) adhering to the substrate surface is sucked from the suction ports 228 through the liquid/gas discharge pipe 230 which communicates with a vacuum source and thus is under vacuum suction.

In the embodiment illustrated in the Figures, each cleaning section has two working faces each with the arrangement of supply ports and suction ports, so that two types of fluids (liquids) can be used. Thus, the cleaning sections 112, 115 each include two liquid/gas discharge pipes 230, 230 and two supply pipes 229, 229. A pair of supply pipe 229 and liquid/gas discharge pipe 230 is connected to those supply ports 227 and suction ports 228 which open in one working face K1, whereas the other pair of supply pipe 229 and liquid/gas discharge pipe 230 is connected to those supply ports 227 and suction ports 228 which open in the other working face K2. The supply ports 227 and the suction ports 228 may also be arranged in such a manner that supply sections and suction sections, each section being comprised of one or more supply ports 227 or suction ports 228, are arranged alternately, such as the arrangement of supply port 227, supply port 227, suction port 228, supply port 227, supply port 227, suction port 228 . . . .

Switching between the working faces K1 and K2 can be performed by rotating the cleaning nozzles 112, 115 by 90 degrees about their respective central axes O₁, O₂ (see FIGS. 34B and 34C) by using not-shown rotating means. The switching enables the same cleaning nozzles 112, 115 to carry out different types of processing using different types of fluids (liquids). It is possible to carry out chemical processing or etching of a substrate by using the working face(s) K1, and subsequently carry out rinsing of the substrate with a rinsing liquid, such as pure water, by using the working face(s) K2 to replace a fluid (liquid), remaining on the substrate after the first processing, with the rinsing liquid. In the embodiment showing in the Figures illustrates the case of supplying a processing liquid from the cleaning nozzles 112, 115 using their working faces K1 to process the upper and lower surfaces of the substrate W.

As shown in FIG. 36A, each supply port and each suction port are preferably disposed at a predetermined distance from a substrate surface. This makes it possible to supply a fluid (liquid) to the substrate surface with the same supply distance from all the supply ports, enabling uniform processing of the substrate surface. Further, because of the same distance between the substrate surface and all the suction ports, the suction forces of all the suction ports, acting on the substrate surface, can be equalized without variation.

The supply ports 227 are preferably disposed in the vicinity of and at the same distance from a substrate surface such that the distance between the front end of each supply port 227 and the substrate surface is preferably not more than 2 mm, more preferably not more than 0.5 mm. Similarly, the suction ports 228 are preferably disposed in the vicinity of and at the same distance from the substrate surface such that the distance between the front end of each suction port 228 and the substrate surface is preferably not more than 2 mm, more preferably not more than 0.5 mm. The distance between the supply ports 227 and the substrate surface may not necessary be the same as the distance between the suction ports 228 and the substrate surface. By thus disposing the supply ports 227 and the suction ports 228 in the vicinity of a substrate, a fluid (liquid) supplied to the substrate can be kept stationary with respect to the substrate and, in addition, the suction efficiency can be increased. A fluid (liquid) is supplied from each supply port preferably at a flow rate of 1 to 30 mL/min. Especially when supplying a liquid chemical to react it with a substrate surface, the flow rate is preferably 1 to 10 mL/min, more preferably 1 to 5 mL/min. For example, in the case of a wafer having a diameter of 200 mm, a fluid (liquid) may be supplied form each supply port at a flow rate of about 30 mL/min to clean one surface of the substrate. The supply of a fluid (liquid) at such a low flow rate offers the advantages of little spattering of the fluid (liquid) during processing and a very small amount of liquid remaining on a substrate after processing. In order to prevent a fluid (liquid) supplied from a supply port to a substrate from being directly sucked into a suction port, the supply ports 227 and the suction ports 228 preferably have a bottom-top height “d” and are arranged at a spacing “s” (see FIG. 36A). The height “d” and the spacing “d” are preferably at least 1 mm.

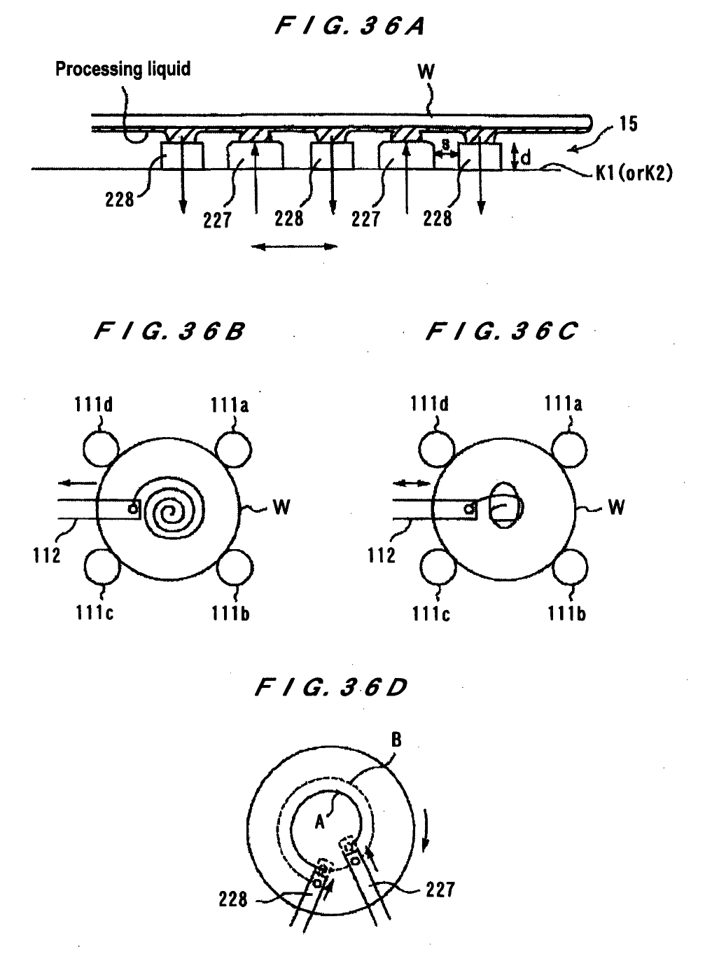

The cleaning nozzles 112, 115 are each reciprocatable along the radial direction of a substrate to be cleaned, as shown by the arrow in FIG. 35. The reciprocating direction of nozzles may not necessarily be aligned with the direction of arrangement of the cleaning nozzles. Thus, as shown in FIG. 36A, in operation of the cleaning nozzles, a fluid (liquid) is supplied (in a stationary state) to a substrate W from the fluid (liquid) supply ports 227 in the vicinity of the substrate W, while after a certain time the superfluous fluid (liquid) remaining on the substrate W is removed by suction through the suction nozzles 228 spaced apart from the supply ports 227. In conventional apparatuses, a fluid (liquid) supplied to a substrate W is removed by centrifugal force by rotating the substrate at a high speed. In contrast, according to the present cleaning section, a fluid (liquid) supplied to a substrate W is kept in such a stationary state that the liquid on the substrate does not move relative to the substrate and is allowed to remain on the substrate for at least a certain length of time so that the fluid (liquid) can fully react with the substrate surface, and the fluid (liquid) after the reaction with the substrate surface is sucked into the suction ports which have reached the fluid (liquid) by the radial reciprocation of the cleaning nozzle. It is desirable with such present cleaning nozzles to supply a fluid (liquid) in such a manner that the fluid (liquid) is applied or printed, in the form a substantially-uniform thin film having a predetermined thickness, on the entire substrate surface by the reciprocation of the supply ports along the radial direction of the substrate and by the rotation of the substrate. For this purpose, the fluid (liquid) supply flow speed is preferably as low as possible. In particular, the fluid (liquid) supply flow speed is preferably not more than 5 m/s, more preferably not more than 1 m/s. The rotational speed of the substrate W is preferably not more than 500 min⁻¹, especially not more than 100 min⁻¹.

This cleaning method, which utilizes the combination of supply and suction of a fluid (liquid), can significantly reduce the amount of the fluid (liquid) used as compared to the common method of supplying a fluid (liquid) to the center of a substrate, followed by spin-drying. Further, spattering of the fluid (liquid) can be prevented by sucking in the fluid (liquid) supplied to a substrate W. Further, by the suction of the fluid (liquid), the amount of the fluid (liquid) remaining on the substrate W and a thickness of the remaining liquid can be kept constant over the entire substrate surface, enhancing the stability and uniformity of the processing.

As described above, this cleaning section is to supply (in a stationary manner) a fluid (liquid) to an intended portion of a substrate W, and not to spread the fluid (liquid) over the entire substrate W by rotating the substrate W at a high speed. Processing at a low rotational speed, e.g., around 100 min⁻¹, is therefore preferred. In the case of the method of supplying a fluid (liquid) to the center of a substrate W and spreading the fluid (liquid) over the entire substrate W by the rotation of the substrate, it is generally necessary to rotate the substrate W, for example at a rotational speed of 500 min⁻¹ for a 200-mm semiconductor substrate, and to supply the fluid (liquid) at a flow rate of at least 0.5 L/min to one surface of the substrate. On the other hand, this cleaning section, which utilizes the repetition of supply and suction of a fluid (liquid) as described above, enables sufficient cleaning of a substrate even when supplying the fluid (liquid) at such a low flow rate as about 30 mL/min.

The cycle time for the reciprocating of the supply ports and the suction ports along the radial direction of a substrate W should be made longer than the cycle time for the rotation of the substrate. Should the cycle time for the rotation of the substrate be the same as the cycle time for the reciprocation of the cleaning section, supply and suction of a fluid (liquid) from a supply port and a suction port would be performed always at the same position on the substrate, resulting in non-uniform processing. On the other hand, when the cycle time for the reciprocation of the cleaning section is longer than the cycle time for the rotation of the substrate, the substrate will make, e.g., several revolutions per one cycle of reciprocation of the cleaning section, whereby the fluid (liquid) will be supplied to and sucked in from the substrate in a spiral manner (see FIGS. 36B and 36D). Should the cycle time for the reciprocation of the cleaning section be made shorter than the cycle time for the rotation of the substrate, the fluid on the substrate would trace a complicated pattern (see FIG. 36C). Since with this cleaning method the fluid (liquid) on the substrate is thus sucked in some time after supply of the fluid, the fluid (liquid) can be given a sufficient time for reaction, enabling uniform processing.

During the reciprocation of the supply ports and the suction ports, the stop time at the moving end is preferably within 0.5 second. During the stop time when the cleaning section reverses its moving direction in the reciprocation, a liquid is kept supplied to the same position on a substrate. Accordingly, the stop time is preferably as short as possible. For example, when the cycle time of the reciprocation is 5 seconds, the stop time at the moving end is preferably within 0.5 second, more preferably within 0.1 second.

As shown in FIG. 35, the supply ports 227 of the cleaning nozzle 115 are preferably allowed to move in a range in the radius direction of a substrate, excluding the center Wo and the peripheral end of the substrate. If a supply port for a fluid (liquid) is moved to the center Wo of the substrate, the fluid (liquid) will be supplied to the center Wo of the substrate in a larger amount as compared to the other portion of the substrate, which is undesirable. It is therefore preferred that the moving range of the supply ports 227 not include the center Wo: the support ports 227 can only move to a position in the vicinity of the center Wo. If the fluid (liquid) is supplied to the peripheral end of the substrate, the fluid (liquid) can spatter out of the substrate. The limitation on the moving range of the supply ports is therefore necessary.

Though in the cleaning sections (cleaning nozzles) shown in FIGS. 34A through 34D, the fluid (liquid) supply ports and suction ports are alternately arranged in line at regular intervals, the above-described cleaning effect could also be attained if the supply ports and the suction ports are not arranged exactly in the same manner. Though, in this embodiment, the cleaning section has two working faces, and the fluid (liquid) supply ports and suction ports are arranged in each working face, it is also possible to arrange the fluid (liquid) supply ports and suction ports only in one working face and arrange supply ports for another fluid (liquid) in the other working face. It is also possible to arrange supply ports and suction ports for a fluid or fluids (liquids) in three or more working faces. The cleaning sections 112, 115 may each have a polygonal or circular cross section, and may each comprise two or more working nozzles. The cross section may be of a combination of polygonal and circular shapes, as shown in FIGS. 34B and 34C.

It is preferred to pre-adjust the respective aperture sizes of the plurality of fluid (liquid) supply ports 227, shown in FIG. 34A, to control the respective flow rates of a cleaning fluid (liquid) supplied from the supply ports 227 so that the flow rate of the cleaning liquid supplied increases with radial distance from the center to the periphery of the substrate. This cleaning section is kept in the vicinity of a rotating substrate while supplying a fluid (liquid) to the substrate. Accordingly, the surface area to which the liquid is to be supplied per unit time increases with radial distance from the center of the substrate. It is therefore necessary to increase the flow rate of the fluid (liquid) supplied from the supply ports with radial distance from the center of the substrate so as to meet the increasing area for supply of the fluid (liquid), making it possible to supply the fluid (liquid) uniformly over the entire surface of the substrate.

It is preferred to provide means for monitoring the flow rate of a fluid (liquid) for at least one of the plurality of supply ports. For example, the flow rate/flow speed of a fluid (liquid) supplied from each supply port can be calculated from the aperture diameter or size of the supply port by detecting the supply pressure of the fluid (liquid). By controlling the supply pressure to maintain a predetermined flow rate/flow speed, the precision of the flow rate of a fluid (liquid), such as a cleaning liquid, can be enhanced, enabling precision cleaning. The substrate processing unit preferably includes a temperature control means for carrying out either one or both of heating and cooling of a fluid (liquid). The substrate processing properties of a fluid (liquid) are often temperature-dependent. In such a case, the temperature of the fluid (liquid) preferably can be adjusted to an appropriate temperature. The temperature control means may be exemplified by a heater or a cooling section provided in a fluid (liquid) supply pipe.

On the other hand, the suction ports 228 are each configured (as to their respective shapes and sizes) to be capable of adjusting the conductance. The respective suction ports 228 suck in a processing fluid (liquid) either by the same vacuum source or respectively by different vacuum sources, the both vacuum sources each being controlled at a predetermined suction pressure. The suction flow rate/flow speed of a processing fluid (liquid) sucked into each suction port 228 can be varied individually by arbitrary setting the aperture size of the suction port. Even after setting the aperture size of the suction port 228, the suction flow rate/flow speed can be changed by changing the suction intensity of the vacuum source. From the viewpoint of uniformly processing the entire surface of a substrate W, it is preferred to make the suction flow rate not exceed the supply flow rate at any radial position on the substrate W and to either equalize the suction flow rates of the suction ports 228 or decrease the suction flow rate with radial distance from the center of the substrate W (i.e., to constantly deposit a processing liquid with a uniform thickness on the entire substrate surface and to replace the processing liquid by supply/suction of the liquid at a uniform speed over the entire substrate surface).

It is possible to provide means for setting processing conditions, such as the rotational speed of substrate, the distance between the cleaning sections 112, 115 and the substrate, the cycle time, the average speed and the maximum speed of the reciprocation of the cleaning sections 112, 115, the supply pressure and temperature of the fluid (liquid) supplied, the vacuum intensity of the vacuum source, the type of the fluid (liquid), etc., depending on the type of the substrate (wafer) to be processed and the type of a film formed on the surface of the substrate; monitoring measurement values for such processing conditions during processing of the substrate, and comparing the measurement values with the preset date on the processing conditions; and controlling the substrate processing process so as to maintain the preset processing conditions.

A bevel cleaning means may be provided in the substrate processing unit having the cleaning section 115 for processing a lower surface of a substrate. This enables cleaning or etching of a back surface of a substrate to be carried out simultaneously with bevel processing of the substrate. Alternatively, it is possible to dispose the cleaning section 112 over the upper surface of a substrate, and provide a bevel cleaning means for processing the peripheral end area of the lower surface.

It is preferred to provide means for recovering and reusing a fluid (liquid) which has been sucked into the suction ports. For example, it is preferred to recover the used fluid (liquid) in a recovery tank and, after filtering the fluid (liquid) with a filter, return the fluid (liquid) to a fluid (liquid) supply tank provided in the present substrate processing unit. It is preferred to further provide means for regenerating the recovered fluid (liquid). This will promote reuse of the fluid (liquid), leading to further resource saving. Furthermore, it is also preferred to provide means for monitoring the concentration of the recovered or regenerated fluid (liquid), the concentration of impurities in the fluid (liquid), or the like.

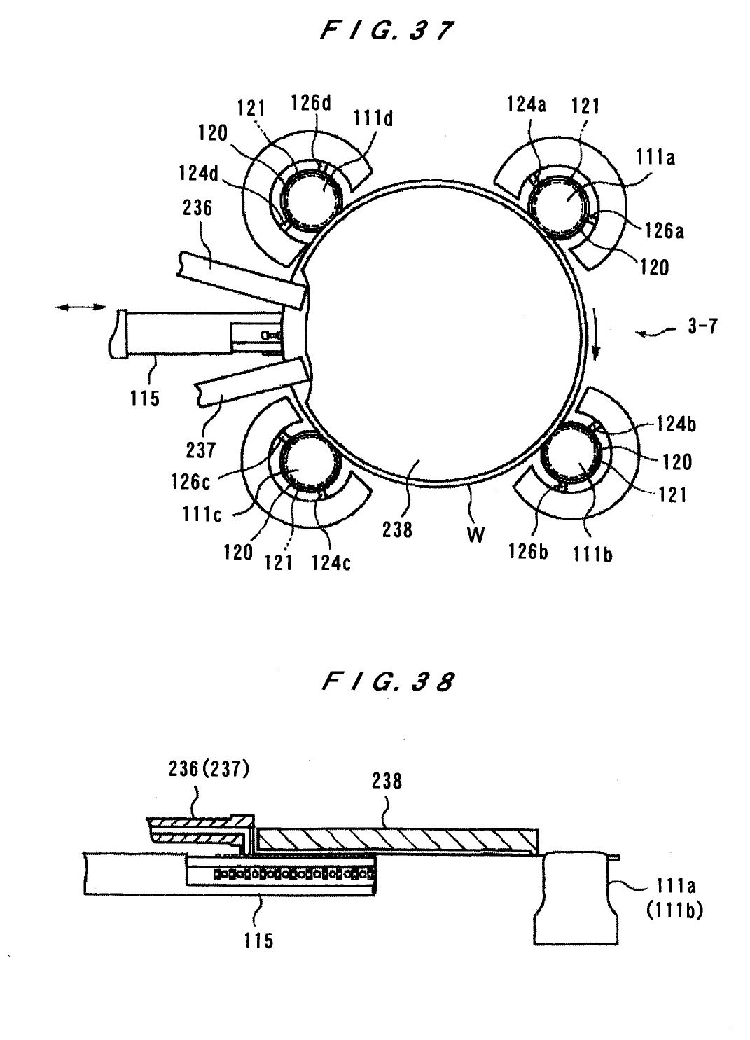

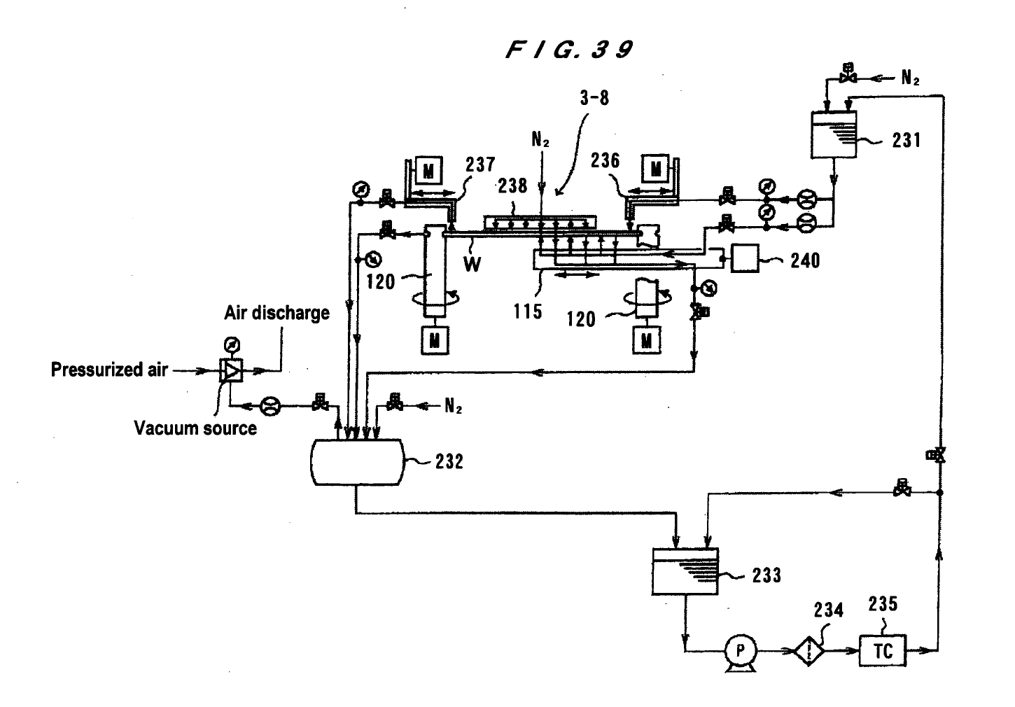

FIGS. 37 and 38 schematically shows the construction of a substrate processing unit 3-7 according to another embodiment of the present invention, and FIG. 39 shows the construction of a system of the substrate processing unit 3-7. The substrate processing unit 3-7 is the same as the preceding embodiment in that a substrate W to be processed is rotatably held by the substrate holders 111a, 111b, 111c, 111d, comprised of rollers, and that the substrate W is processed while sucking in a processing liquid by the holder suction nozzles 124 (124a, 124b, 124c, 124d) and supplying a cleaning liquid to the clamp portions 121 from the holder cleaning nozzles 126 (126a, 126b, 126c, 126d). In this embodiment, however, the cleaning section 115 is provided only on the lower surface side of the substrate W, and a purge plate 238, which is movable horizontally and vertically, is provided on the upper surface side of the substrate W. The purge plate 238 has a not-shown opening(s) so that an inert gas, such as N₂ gas, is supplied from the opening(s) to the substrate W, such as a semiconductor wafer. This can prevent contamination or deterioration of the substrate surface with a mist of fluid (liquid) or a chemical atmosphere, coming from the lower surface side of the substrate W. Only one opening may be provided in the purge plate 238 at a position corresponding to the center of the substrate W. Alternatively, a plurality of openings may be provided in the purge plate 238 such that the openings are disposed along a plurality of circles concentric to the substrate W and at regular intervals in radial directions.

The substrate processing unit 3-7 also includes a bevel cleaning nozzle 236 for cleaning a peripheral portion (bevel portion) of the substrate, and a bevel suction nozzle 237 for sucking in a cleaning liquid. Thus, a cleaning liquid supplied from the bevel cleaning nozzle 236 is sucked into the bevel suction nozzle 237 and removed immediately before the substrate W makes one revolution in the direction of the arrow after the supply of the liquid. This unit can thus carry out cleaning of the back surface of the substrate and processing, such as cleaning, of the bevel portion of the front surface of the substrate. It is also possible to carry out processing, such as etching, by using the nozzles, and subsequently carry out cleaning. The bevel cleaning nozzle 236 and the bevel suction nozzle 237 are each movable in the radial direction of the substrate W by a motor M so that the peripheral processing area of the substrate can be adjusted. It is also possible to reciprocate the bevel cleaning nozzle 236 and the bevel suction nozzle 237 from the center to the periphery of the substrate so as to process the entire surface of the substrate. The purge plate 238 has a generally-circular shape, not covering a peripheral portion of the substrate W so as not to interfere with the bevel cleaning nozzle 236 and the bevel suction nozzle 237.

In the substrate processing unit 3-7, as shown in FIG. 39, a liquid chemical is supplied from a chemical pressure feed tank 231 to the cleaning section 115, and the liquid chemical is supplied from the supply ports of the cleaning section 115 to the surface of the substrate W. The cleaning section 115 reciprocates horizontally by the motor M, as illustrated in the Figure, and recovers the liquid chemical, supplied to the substrate, from the suction ports. The liquid chemical, recovered from the suction ports, is first sent to a recovery tank (gas-liquid separation tank) 232, where the chemical is subjected to gas-liquid separation, and then sent to a circulation tank 233.

The used liquid chemical stored in the circulation tank 233 is pressurized by a pump P and filtered by a filter 234 and, after its temperature is adjusted by a temperature controller 235, is returned as a reusable chemical to the chemical pressure feed tank 231. The system thus enables recycling of the liquid chemical, thereby saving resource of the liquid chemical. A liquid chemical, which is supplied from the bevel cleaning nozzle 236 to the bevel portion of a substrate and sucked into the bevel suction nozzle 237, can also be recycled. Though not shown diagrammatically, it is also possible to provide means for regenerating the used chemical, which has returned to the circulation tank 233, to regenerate and reuse the used chemical.

It is preferred that the following characteristic constructions of the substrate processing unit 3-4 be applied, to the extent possible, to the substrate processing units 3-5 to 3-7:

(1) Provision of air intakes, disposed symmetrically with respect to a substrate, to create an air curtain uniformly encircling the substrate;

(2) Provision of roller covers to cover rollers which make direct contact with a substrate;

(3) Provision of a nozzle cover to cover a gas jet nozzle in a retreat position; and

(4) Provision of an inner wall cleaning nozzle to carry out self-cleaning of an inner wall.

### INDUSTRIAL APPLICABILITY

The substrate cleaning apparatus and the substrate processing unit of the present invention can be used for cleaning a substrate (e.g., semiconductor wafer) for use in the manufacturing of a semiconductor device.

1. A substrate cleaning apparatus comprising a base-integrated frame in which are mounted a substrate transport device for transporting a substrate, at least one substrate processing unit for processing the substrate, a substrate loading port for placing a substrate-housing cassette thereon, and a processing liquid supply apparatus for supplying a processing liquid to the substrate processing unit, wherein maintenance of the substrate processing unit can be performed from the backside of the apparatus.

2. The substrate cleaning apparatus according to claim 1, wherein at least one of the at least one substrate processing unit is a substrate processing unit capable of completing a substrate processing process by itself by carrying out a final drying step.

3. The substrate cleaning apparatus according to claim 1, wherein at least one of the at least one substrate processing unit is a substrate processing unit capable of carrying out at least one of cleaning of the both surfaces of the substrate, bevel etching of the substrate and scrubbing of one surface of the substrate, and also capable of carrying out drying of the substrate.

4. A substrate cleaning apparatus comprising:
a substrate loading port for placing a substrate-housing cassette thereon;
a substrate processing unit for processing a substrate; and
a substrate transport device, disposed between the substrate loading port and the substrate processing unit, for transporting the substrate only between the substrate loading port and the substrate processing unit.

5. The substrate cleaning apparatus according to claim 1, wherein the substrate processing unit is disposed parallel to the substrate loading port.

6. The substrate cleaning apparatus according to claim 1, wherein the processing liquid supply apparatus is capable of supplying two or more types of processing liquids to the substrate processing unit.

7. The substrate cleaning apparatus according to claim 6, wherein the processing liquid supply apparatus includes a plurality of supply tanks for each processing liquid.

8. The substrate cleaning apparatus according to claim 7, wherein the processing liquid is supplied alternately from the plurality of supply tanks.

9. The substrate cleaning apparatus according to claim 3, wherein a substrate drying means is provided in all of the at least one substrate processing unit.

10. The substrate cleaning apparatus according to claim 9, wherein the substrate drying means includes a gas jet means for jetting an inert gas to the front and back surfaces of the substrate.

11. The substrate cleaning apparatus according to claim 3, including a purge plate for jetting an inert gas toward a peripheral portion of the substrate for drying of the substrate surface after the bevel etching of the substrate in the substrate processing unit.

12. The substrate cleaning apparatus according to claim 11, wherein the purge plate is adapted to jet the inert gas from at least two openings, one facing a peripheral portion of the substrate and the other facing an inner portion of the substrate.

13. The substrate cleaning apparatus according to claim 1, wherein the substrate transport device is a fixed transport robot without a travel axis.

14. A substrate processing apparatus comprising:
a substrate transport device for transporting a substrate;
a substrate processing unit for processing the substrate;
a substrate loading port for placing a substrate-housing cassette thereon; and
a processing liquid supply apparatus for supplying a processing liquid to the substrate processing unit;
wherein the following relation is maintained:
PA>PO>PB,
wherein PO represents atmospheric pressure outside the substrate processing apparatus, PA represents air pressure in a substrate transport chamber in which the substrate transport device is disposed, and PB represents air pressure in the substrate processing unit.

15. A substrate processing unit for use in a processing area to which a clean gas is supplied, comprising:
a chamber disposed in the processing area;
a substrate holder for holding a substrate rotatably in a horizontal plane in the chamber; and
a processing fluid supply means for supplying a processing fluid to the substrate held by the substrate holder;
wherein the chamber is provided with a gas flow-creating means for creating a gas flow, uniformly encircling the substrate held by the substrate holder, by taking said clean gas into the chamber from a gas intake formed above the substrate holder, and discharging the gas from the bottom of the chamber.

16. The substrate processing unit according to claim 15, wherein the gas intake is formed along a periphery of the substrate held by the substrate holder.

17. A substrate processing unit for use in a processing area to which a clean gas is supplied, comprising:
a chamber disposed in the processing area;
a substrate holder for holding a substrate rotatably in a horizontal plane in the chamber;
a processing fluid supply means for supplying a processing fluid to the substrate held by the substrate holder; and
a purge member for covering a surface of the substrate with a gap therebetween and supplying a gas into the gap to prevent intrusion of the processing fluid into the gap;
wherein the purge member comprises a first cover member for covering a first area of the substrate surface and a second cover member for covering a second area of the substrate surface, at least one of the cover members being movable with respect to the other.

18. The substrate processing unit according to claim 15, wherein the substrate holder comprises a plurality of rollers, each having a vertical axis and provided with a roller cover having an opening for the roller to hold the substrate.

19. The substrate processing unit according to claim 15, further comprising:
a gas nozzle for jetting a gas towards the substrate; and
a nozzle cover for covering the gas nozzle when not in use.

20. The substrate processing unit according to claim 15, further comprising:
a cleaning liquid supply means for cleaning the inner wall of the chamber with predetermined timing.

21. A substrate cleaning apparatus comprising:
the substrate processing unit according to claim 15;
a frame forming a space in which the substrate processing unit is housed; and
a gas supply means for supplying a clean gas to said space.

22. The substrate cleaning apparatus according to claim 15, wherein the substrate holder is provided with a holder suction section for sucking in the processing fluid.

23. The substrate cleaning apparatus according to claim 15, wherein the substrate holder comprises a plurality of rollers for bringing into contact with an edge of the substrate to rotate the substrate, said rollers being movable in the radial direction of the substrate.

24. The substrate cleaning apparatus according to claim 1, wherein the substrate processing unit includes a substrate holder for rotatably holding the substrate and processes the substrate by supplying a fluid to the substrate while rotating the substrate, and the substrate holder is provided with a holder suction section for sucking in the fluid.

25. The substrate cleaning apparatus according to claim 1, wherein the substrate processing unit includes:
a substrate holder for horizontally holding and rotating a substrate;
a gas supply nozzle, disposed above and below the substrate held by the substrate holder, for supplying a gas to the substrate;
a liquid supply nozzle, disposed above and below the substrate held by the substrate holder, for supplying a liquid to the substrate; and
a movement mechanism for moving the gas supply nozzle and the liquid supply nozzle from the center to the periphery of the substrate, said liquid supply nozzle being disposed at an outer position than the gas supply nozzle in the radial direction of the substrate.

26. The substrate cleaning apparatus according to claim 1, wherein at least one fluid supply port and at least one suction port, spaced away from each other and located in the vicinity of the rotating substrate, are provided in the processing unit, and a processing fluid is supplied from the fluid supply port to the substrate while the processing fluid adhering to the substrate is sucked into the fluid suction port.

27. The substrate cleaning apparatus according to claim 1, wherein the substrate processing unit includes a substrate holder for holding and rotating the substrate, and the substrate holder comprises a plurality of rollers for bringing into contact with an edge of the substrate to rotate the substrate, said rollers being movable in the radial direction of the substrate.
